(19) United States
(12) Patent Application Publication
(10) Pub. No.: US 2025/0374508 A1
(43) Pub. Date: Dec. 4, 2025

(54) SEMICONDUCTOR DEVICE AND METHOD

(71) Applicant: Taiwan Semiconductor Manufacturing Co., Ltd., Hsinchu (TW)

(72) Inventors: Shih-Hao Lin, Hsinchu (TW); Zi-Yuan Wei, Hsinchu (TW)

(21) Appl. No.: 18/936,402

(22) Filed: Nov. 4, 2024

Related U.S. Application Data
(60) Provisional application No. 63/655,136, filed on Jun. 3, 2024.

(51) Int. Cl. H10B 10/00

(52) U.S. Cl. CPC H10B 10/125

(57) ABSTRACT

In an embodiment, a method may include forming a multi-layer stack over a substrate, the multi-layer stack having alternating layers of first semiconductor layers and second semiconductor layers. The method may also include patterning the multi-layer stack to form a first fin. The method may also include patterning the first fin to form two sub-fins. A method may in addition include forming recesses in the two sub-fins. The method may also include selectively removing the first semiconductor layers. The method may also include forming a sacrificial material between the second semiconductor layers. The method may also include growing epitaxial source/drain regions in the recesses, and replacing the sacrificial material with an active gate structure.

### PRIORITY CLAIM AND CROSS-REFERENCE

This application claims the benefit of U.S. Provisional Application No. 63/655,136 filed on Jun. 3, 2024, entitled “GAA STRUCTURE DESIGN WITH DOI ENGINEERING,” which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4A, 4B, 5A, 5B, 6A, 6B, 7A, 7B, 8A, 8B, 9A, 9B, 10A, 10B, 10C, 11A, 11B, 11C, 12A, 12B, 12C, 12D, 13A, 13B, 13C, 13D, 14A, 14B, 14C, 14D, 15A, 15B, 16A, 16B, 17A, 17B, 18A, 18B, 18C, 18D, 19A, 19B, 19C, 20A, 20B, 20C, 21A, 21B, and 21C illustrate varying views of intermediary steps of manufacturing a nano-FET transistor, in accordance with some embodiments.

FIG. 22 illustrates a cross-sectional view of an intermediary step of manufacturing a nano-FET transistor, in accordance with some embodiments.

FIG. 23 illustrates a cross-sectional view of an intermediary step of manufacturing a nano-FET transistor, in accordance with some embodiments.

FIG. 24 illustrates a cross-sectional view of an intermediary step of manufacturing a nano-FET transistor, in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a method for nano-FET (e.g., nanowire FET, nanosheet FET (Nano-FETs), or the like) formation using a disposable oxide interposer (DOI) scheme. This disclosure incorporates DOI engineering for nanosheet static random access memory (SRAM) cells. By increasing the effective channel width of pass-gate (PG) and pull-down (PD) transistors, the structure optimizes SRAM cell performance and mitigates current crowding issues that become more pronounced at smaller nodes. In some embodiments, the increased effective channel width is achieved because a stack of nanostructures that are cut lengthwise forming two stacks of nanostructures (with each nanostructure having four sides contributing to the effective channel width), which can increase the effective channel width of the device. The DOI scheme minimizes sheet-width loss during the sheet-release stage of fabrication, resulting in substantial improvements in direct current (DC) performance and reduced variability (sigma). In some embodiments, the pull-up (PU) transistors also increased effective width.

The fabrication process utilizes nanostructure cut techniques, allowing for flexible implementation through either separate or single cut active area masks for NMOS and PMOS devices. This approach enables the creation of optimized transistor structures for both n-type and p-type devices within the same manufacturing process, facilitating the production of complementary metal-oxide-semiconductor (CMOS) circuits with enhanced performance characteristics.

There are several advantages of the disclosed semiconductor device and fabrication method. The increased effective width of PG and PD transistors not only optimizes SRAM cell performance but also reduces current crowding, resulting in improved read and write margins and enhanced overall cell stability. These improvements help maintain reliable SRAM operation as supply voltages are scaled down in advanced nodes.

The DOI scheme's ability to minimize sheet-width loss translates directly into gains in DC performance. This is useful for SRAM applications, where fast switching speeds and low power consumption are advantageous. The optimized structure achieves an 8-15% improvement in cell current, which directly correlates to faster SRAM operation speeds and improved overall performance metrics.

Furthermore, the enhanced PG/PD performance allows for optimization of the SRAM Cell V_{ccmin} (minimum operating voltage), enabling reliable operation at lower supply voltages. Specifically, the optimized structure results in a 17-33% improvement for the SRAM cell V_{ccmin}. This capability helps to reduce power consumption in modern semiconductor devices, particularly in mobile and battery-powered applications where energy efficiency is more beneficial.

The combination of these advancements-improved electrostatic control, enhanced DC performance, increased cell current, and lower operating voltages-makes this nano-FET structure and method a solution for the continued scaling of SRAM technology in advanced semiconductor nodes. By addressing challenges of transistor scaling while simultaneously improving performance metrics, disclosed embodiments enable high-performance, low-power semiconductor devices.

Embodiments are described below in a particular context, a die comprising nano-FETs. Various embodiments may be applied, however, to dies comprising other types of transistors (e.g., stacking transistors, or the like) in lieu of or in combination with the nano-FETs.

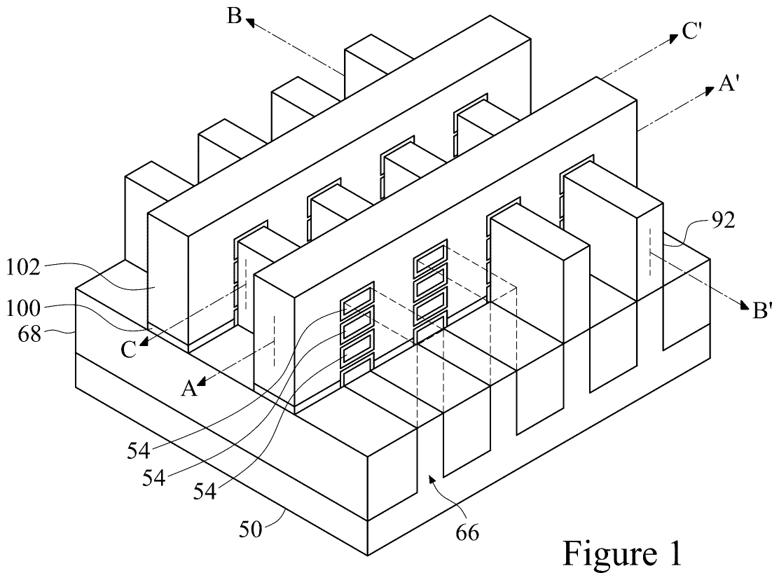

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

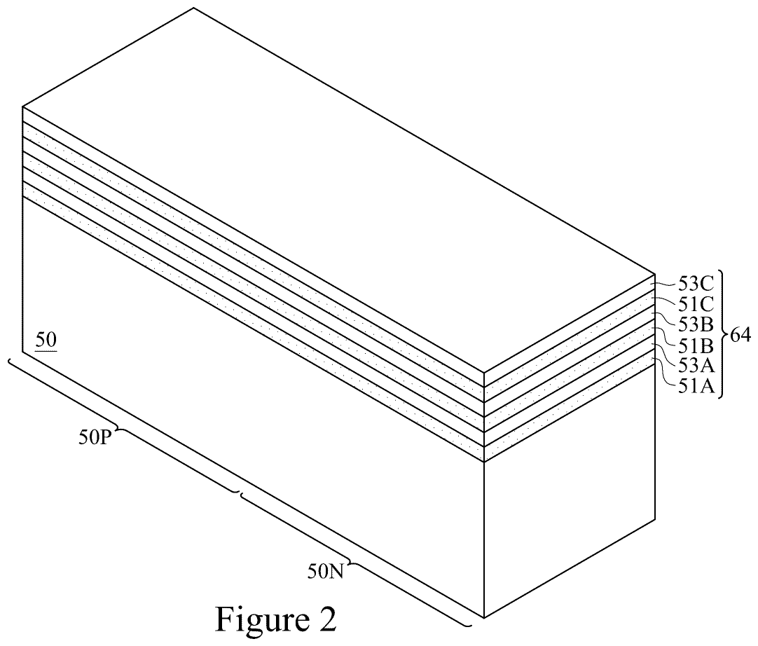

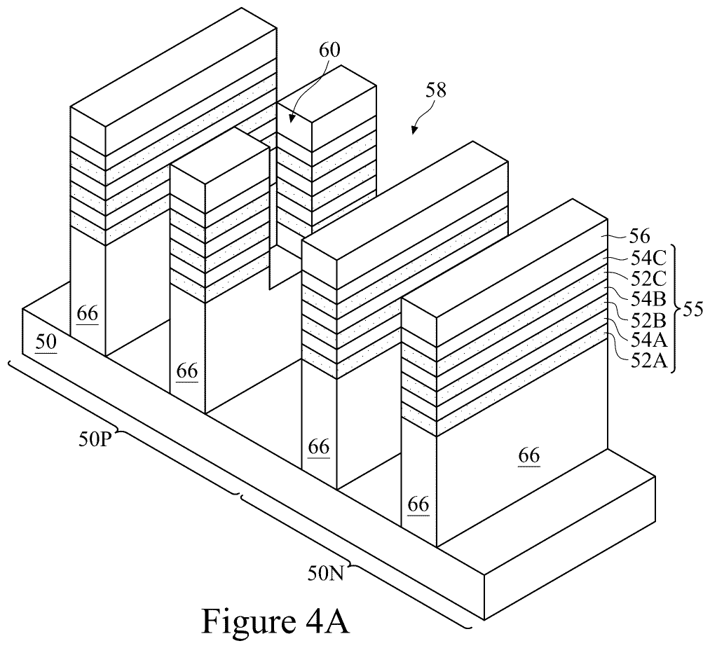

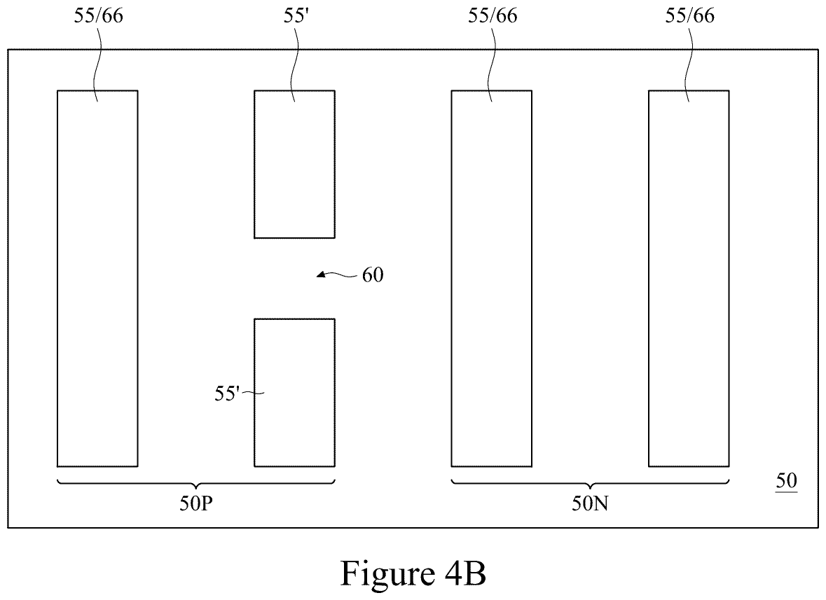

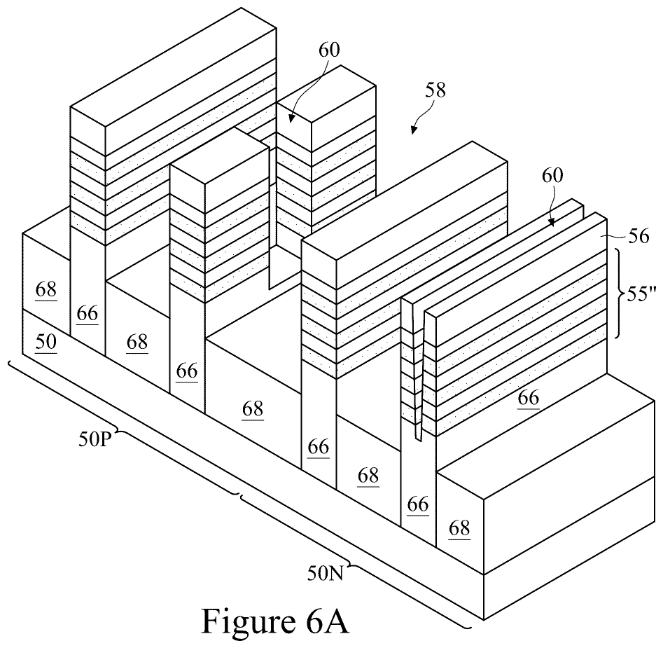

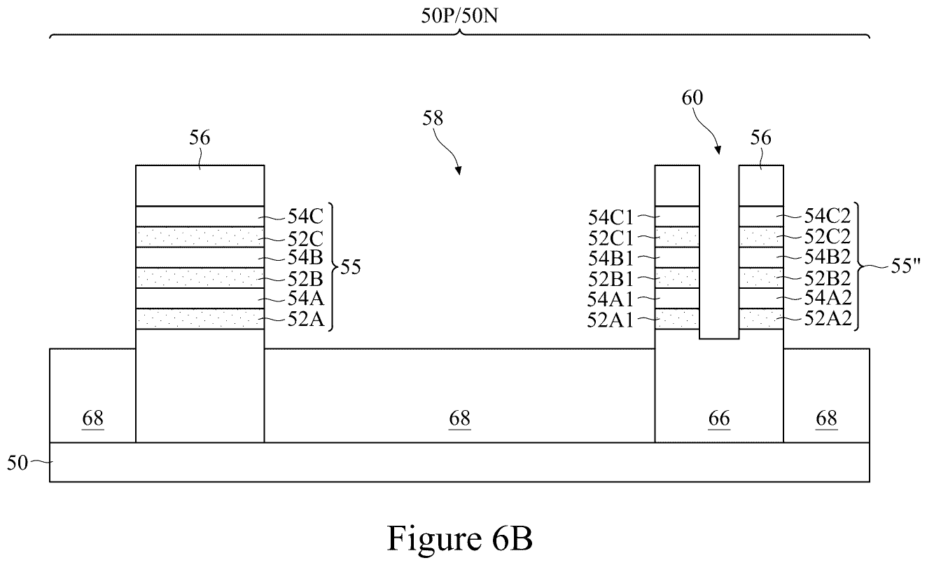

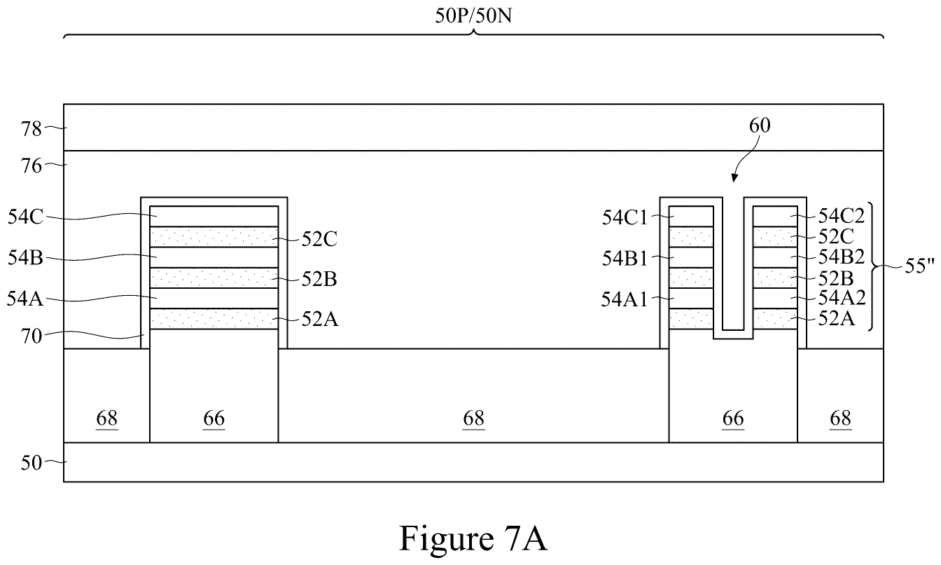

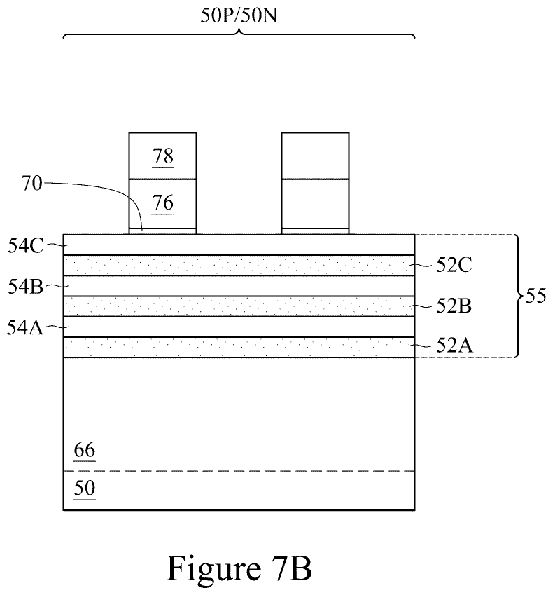

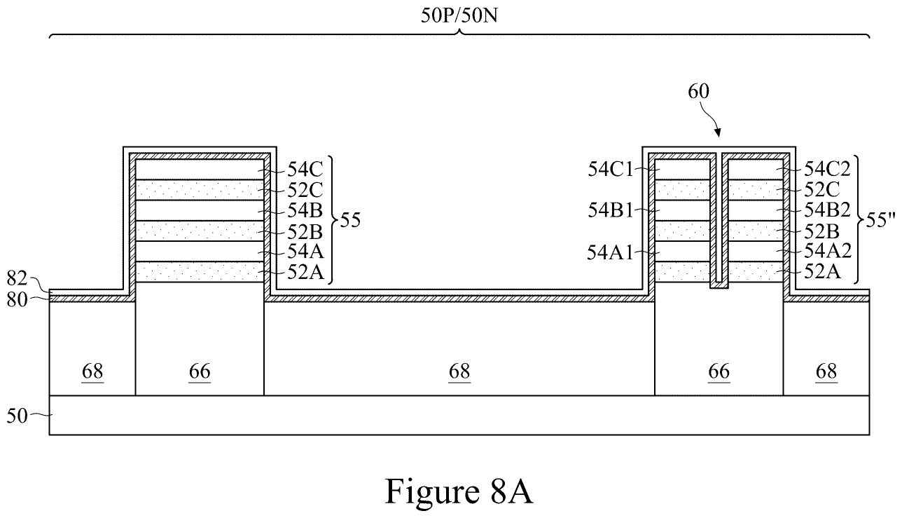

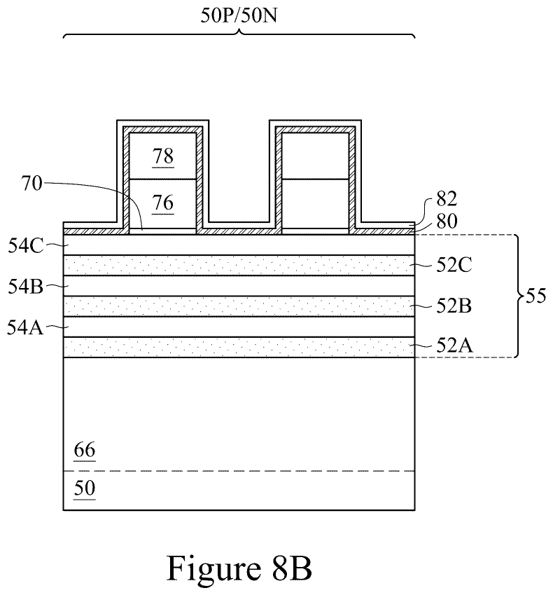

FIGS. 2 through 21C are cross-sectional views of intermediate stages in the manufacturing of nano-FETs, in accordance with some embodiments. FIGS. 2, 3, 4A, 5A, and 6A illustrate three-dimensional views, in accordance with some embodiments. FIGS. 6B, 7A, 10A, 11A, 12A, 13A, 14A, 15A, 16A, 17A, 18A, 19A, 20A, and 21A illustrate reference cross-section A-A′ illustrated in FIG. 1. FIGS. 7B, 8B, 9B, 10B, 11B, 12B, 12D, 13B, 13C, 13D, 14B, 15B, 16B, 17B, 18B, 18C, 19B, 20B, and 21B illustrate reference cross-section B-B′ illustrated in FIG. 1. FIGS. 8A, 9A, 10C 11C, 12C, 14C, 14D, 19C, 20C, and 21C illustrate reference cross-section C-C′ illustrated in FIG. 1. FIGS. 4B, 5B, and 18D illustrate plan views of intermediate stages in the manufacturing of nano-FETs, in accordance with some embodiments.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

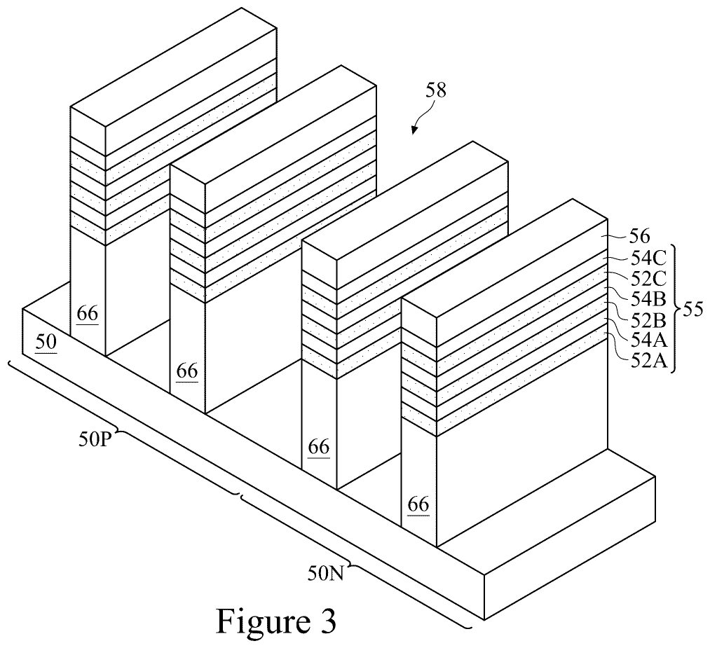

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

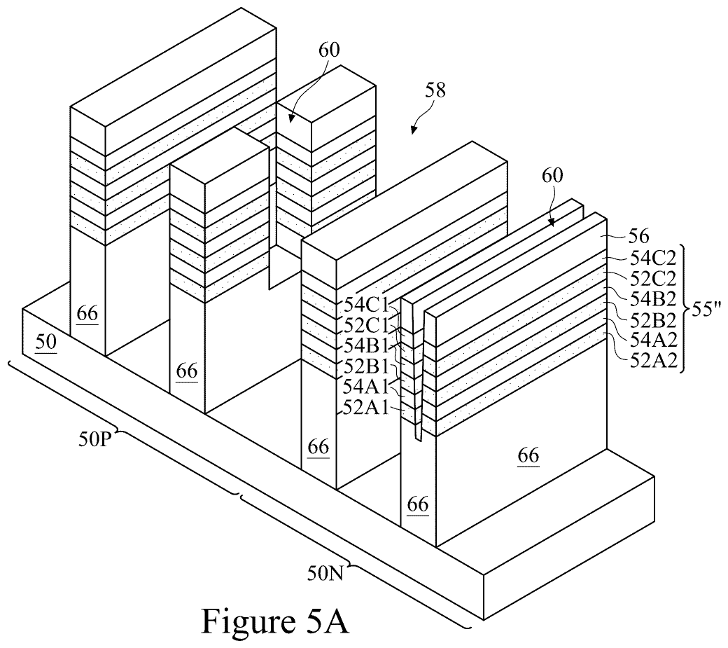

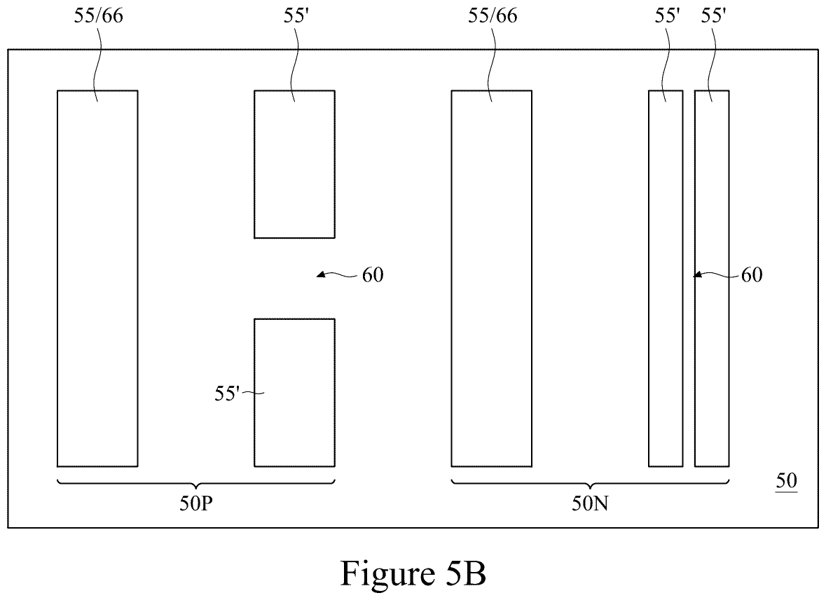

FIGS. 4A and 4B illustrate cutting at least one of the fins 66 and nanostructures 55 into at least two sections or sub-nanostructures 55′. In this embodiment, a first nanostructure cut 60 (may also be referred to as a trench 60 or a gap 60) is in a direction perpendicular to the longitudinal axis of nanostructures 55 and fins 66. In some embodiments, the first nanostructure cut 60 may be formed in a direction along the longitudinal axis of the nanostructures 55 and fins 66 (see, e.g., FIGS. 5A-B).

The first nanostructure cut 60 may be formed using an extreme ultraviolet (EUV) lithography process with one or more mask layers (not shown) formed over the nanostructures 55 and fins 66. EUV lithography is an advanced semiconductor manufacturing technique that uses very short wavelength light (typically 13.5 nm) to pattern extremely small features. This process enables the creation of intricate structures at dimensions below 10 nm. EUV lithography emits EUV light that is focused to project the desired pattern onto a mask, such as a photoresist (not shown). In the context of creating the first nanostructure cut 60 in the nanostructure 55, EUV lithography may provide the precision needed to accurately pattern the narrow gaps and fine features required.

After the EUV patterning of the photoresist, the nanostructures 55 and fins 66 may be patterned using an etching process to form the first nanostructure cut 60 and forming two sub-nanostructures 55′ out of the single nanostructure 55. The etching may be any acceptable etch process, such as a RIE, NBE, the like, or a combination thereof. The etching may be anisotropic. The nanostructure cut 60 may extend completely through the nanostructure 55 and at least partially into the fin 66. In some embodiments, the first nanostructure cut 60 in FIGS. 4A-B allow for the single nanostructure 55 to be cut and be formed into at least two p-type nano-FET devices. In this embodiment, the first nanostructure cut 60 is perpendicular to the longitudinal axis of the nanostructure 55 and results in sub-nanostructures 55′ that have the same width as the prior nanostructure 55 and have a shorter length than the prior nanostructures 55. Further, in some embodiments, the sub-nanostructures 55′ have the same width as the other nanostructure 55 (see, e.g., nanostructures on the 50N region) and have a shorter length than the other nanostructures 55.

FIGS. 5A and 5B illustrate cutting at least one of the fins 66 and nanostructures 55 into at least two sub-nanostructures 55″. In this embodiment, a second nanostructure cut 60 is in a direction parallel or along the longitudinal axis of nanostructures 55 and fins 66. In some embodiments, the second nanostructure cut 60 may be formed in a direction perpendicular to the longitudinal axis of the nanostructures 55 and fins 66 (see, e.g., FIGS. 4A-B).

As illustrated in FIGS. 5A and 5B, the first nanostructures 52A-C and the second nanostructures 54A-C have been cut to form first nanostructures 52A1-C1, 52A2-C2 and second nanostructures 54A1-C1 and 54A2-C2. In the sub-nanostructures 55″, the nanostructure cut 60 forms two separate vertical stacks of second nanostructures 54A1-C1 and 54A2-C2.

The second nanostructure cut 60 may be formed using an EUV lithography process as described above for FIGS. 4A-B. The nanostructures 55 and fins 66 may be patterned using an etching process to form the second nanostructure cut 60 and forming two sub-nanostructures 55″ out of the single nanostructures 55. The nanostructure cut 60 may extend completely through the nanostructure 55 and at least partially into the fin 66. In some embodiments, the second nanostructure cut 60 in FIGS. 5A-B allow for the single nanostructure 55 to be cut and be formed into at least two n-type nano-FET devices. In this embodiment, the second nanostructure cut 60 is parallel to the longitudinal axis of the nanostructure 55 and results in sub-nanostructures 55′ that have the same length as the prior nanostructure 55 and have a smaller width than the prior nanostructures 55.

By patterning the nanostructures 55 along their longitudinal axis to form two sub-nanostructures 55″ enables the optimization of the width of the channels of the resulting nano-FET devices. For example, the channel width of the combined sub-nanostructures 55″ is greater than the nanostructure 55 before cutting. This is due to the increased surface of the sub-nanostructures 55″ that the subsequently formed gate structure will be in contact with as compared to the surface of the nanostructures 55.

By controlling the width of the second nanostructure cut 60, the effective width of the second semiconductor layers in the sub-stacks can be adjusted and, in some embodiments, effectively increased. This increased effective width can optimize the performance of the logic devices by reducing current crowding and improving the read/write margins of the device.

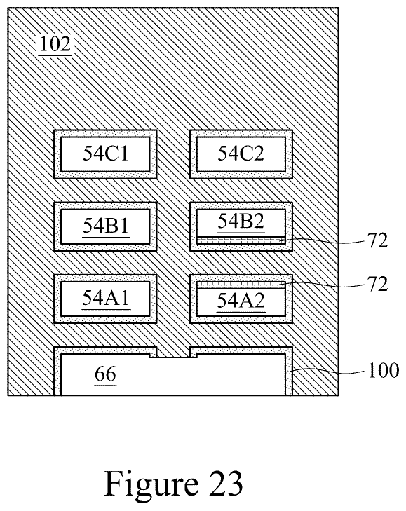

Although the first and second nanostructure cuts 60 were have been discussed and illustrated as being separate processes (e.g., with separate masking and photoresist structures), in some embodiments, the first and second nanostructure cuts 60 may be performed in a same process using the same masking and photoresist structures. Further, although the p-type region 50P has a perpendicular first nanostructure cut 60 and the n-type region 50N has a longitudinal second nanostructure cut 60, in some embodiments, both regions 50N and 50P may have longitudinal nanostructure cuts 60 (see, e.g., FIG. 23), both regions 50N and 50P may have perpendicular nanostructure cuts 60, or on or both regions 50N and 50P may have a combination of longitudinal and perpendicular nanostructure cuts 60 depending on the design of the semiconductor device.

In FIGS. 6A and 6B, shallow trench isolation (STI) regions 68 are formed adjacent the fins 66. The STI regions 68 may be formed by depositing an insulation material over the substrate 50, the fins 66, the nanostructures 55, and the sub-nanostructures 55′/55″, and between adjacent fins 66 to fill the trenches 58. In some embodiments, the insulation material also fills the nanostructure cuts 60. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, the nanostructures 55, and the sub-nanostructures 55′/55″. Thereafter, a fill material, such as those discussed above may be formed over the liner.

A removal process is then applied to the insulation material to remove excess insulation material over the nanostructures 55 and the sub-nanostructures 55′/55″. In some embodiments, a planarization process such as a chemical mechanical polish (CMP), an etch-back process, combinations thereof, or the like may be utilized. The planarization process exposes the nanostructures 55 and the sub-nanostructures 55′/55″ such that top surfaces of the nanostructures 55, sub-nanostructures 55′/55″, and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66, the nanostructures 55, and the sub-nanostructures 55′/55″). For example, an oxide removal using, for example, dilute hydrofluoric (dHF) acid may be used.

Further in FIGS. 6A-B, appropriate wells (not separately illustrated) may be formed in the fins 66, the nanostructures 55, and/or the sub-nanostructures 55′/55″. In embodiments with different well types, different implant steps for the n-type region 50N and the p-type region 50P may be achieved using a photoresist or other masks (not separately illustrated). For example, a photoresist may be formed over the fins 66, the nanostructures 55, and the sub-nanostructures 55′/55″ in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the sub-nanostructures 55′/55″ in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 7A and 7B, dummy gates are formed over and along sidewalls of the nanostructures 55, the sub-nanostructures 55′/55″, and the fin 66. To form the dummy gates, first, a dummy dielectric layer is formed on the fins 66, the nanostructures 55, and/or the sub-nanostructures 55′/55″. The dummy dielectric layer may be, for example, silicon oxide, silicon nitride, a combination thereof, or the like, and may be deposited or thermally grown according to acceptable techniques. The dummy dielectric layer may extend into the nanostructure cuts 60. A dummy gate layer is formed over the dummy dielectric layer, and a mask layer is formed over the dummy gate layer. The dummy gate layer may also extend into the nanostructure cuts 60. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. In some embodiments, the dummy dielectric gate dielectrics 70 and the dummy gates 76 extend into the nanostructure cuts 60 (see, e.g., FIG. 7A). The pattern of the masks 78 may be used to physically separate each of the dummy gates 76 from adjacent dummy gates 76. The dummy gates 76 may also have a lengthwise direction substantially perpendicular to the lengthwise (or longitudinal) direction of respective fins 66. It is noted that the dummy gate dielectrics 70 is shown covering only the fins 66, the nanostructures 55, and the sub-nanostructures 55′/55″ for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

In FIGS. 8A and 8B, a first spacer layer 80 and a second spacer layer 82 are formed over the structures illustrated in FIGS. 7A and 7B. The first spacer layer 80 and the second spacer layer 82 will be subsequently patterned to act as spacers for forming self-aligned source/drain regions. In FIGS. 8A and 8B, the first spacer layer 80 is formed on top surfaces of the STI regions 68; top surfaces and sidewalls of the fins 66, the nanostructures 55, the sub-nanostructures 55′/55″, and the masks 78; and sidewalls of the dummy gates 76 and the dummy gate dielectric 70. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like. As illustrated in FIG. 8A, in some embodiments, the first spacer layer 80 and the second spacer layer 82 may be formed in the nanostructure cuts 60 outside of the dummy gates 76. In some embodiments, only the first spacer layer 80 is formed in the nanostructure cuts 60 as it may fill the cut, or in other embodiments, neither of the spacer layers are formed in the nanostructure cuts 60.

After the first spacer layer 80 is formed and prior to forming the second spacer layer 82, implants for lightly doped source/drain (LDD) regions (not separately illustrated) may be performed. In embodiments with different device types, similar to the implants discussed above in FIGS. 6A and 6B, a mask, such as a photoresist, may be formed over the n-type region 50N, while exposing the p-type region 50P, and appropriate type (e.g., p-type) impurities may be implanted into the exposed fins 66, the nanostructures 55, and the sub-nanostructures 55′/55″ in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66, the nanostructures 55, and the sub-nanostructures 55′/55″ in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 1×10¹⁵ atoms/cm³ to 1×10¹⁹ atoms/cm³. An anneal may be used to repair implant damage and to activate the implanted impurities.

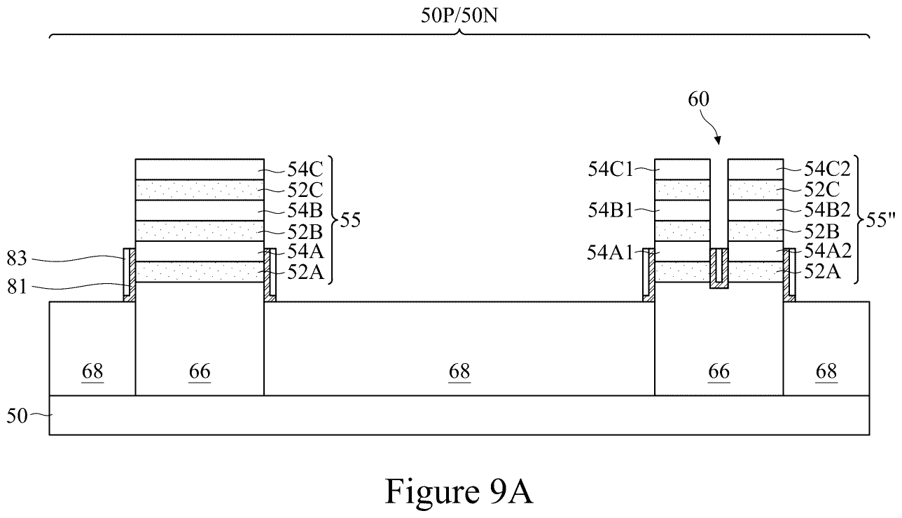

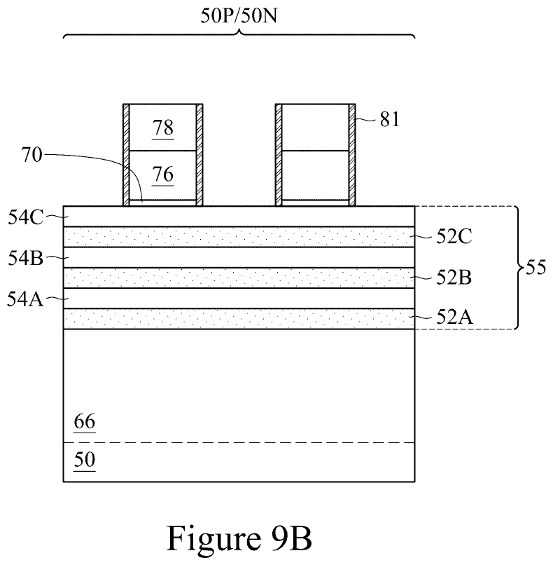

In FIGS. 9A and 9B, the first spacer layer 80 and the second spacer layer 82 are etched to form first spacers 81 and second spacers 83. As will be discussed in greater detail below, the first spacers 81 and the second spacers 83 act to self-align subsequently formed source drain regions, as well as to protect sidewalls of the fins 66, the sub-nanostructures 55′/55″, and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 9A. Thereafter, the second spacers 83 acts as a mask while etching exposed portions of the first spacer layer 80, thereby forming first spacers 81 as illustrated in FIG. 9A. In FIG. 9A, first spacers 81 and second spacers 83 are both formed in the second nanostructure cut 60, but in some embodiments, the spacers are not formed in the second nanostructure cut 60.

As illustrated in FIG. 9A, the first spacers 81 and the second spacers 83 are disposed on sidewalls of the fins 66, the sub-nanostructures 55′/55″, and/or nanostructures 55. As illustrated in FIG. 9B, in some embodiments, the second spacer layer 82 may be removed from over the first spacer layer 80 adjacent the masks 78, the dummy gates 76, and the dummy gate dielectrics 70, and the first spacers 81 are disposed on sidewalls of the masks 78, the dummy gates 76, and the dummy gate dielectrics 70. In other embodiments, a portion of the second spacer layer 82 may remain over the first spacer layer 80 adjacent the masks 78, the dummy gates 76, and the dummy gate dielectrics 70.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

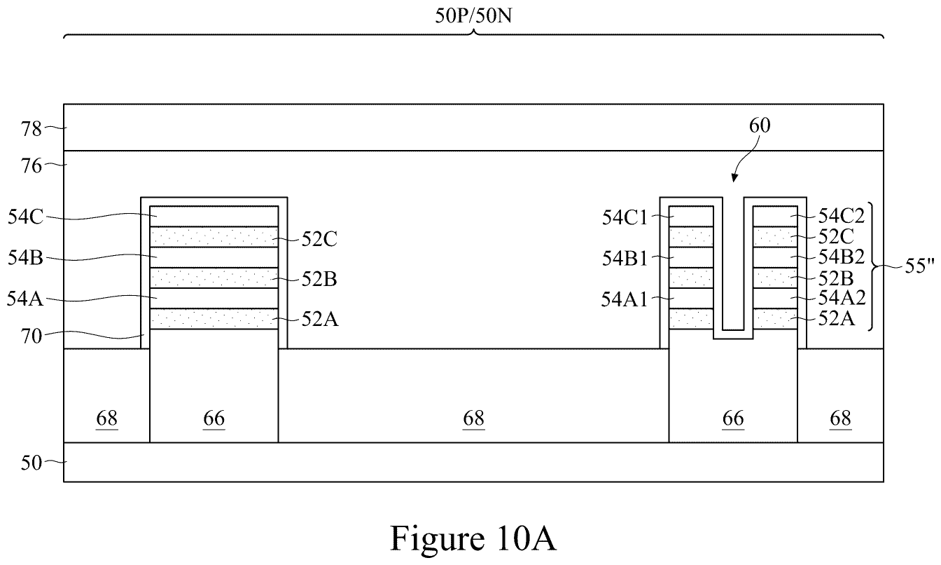

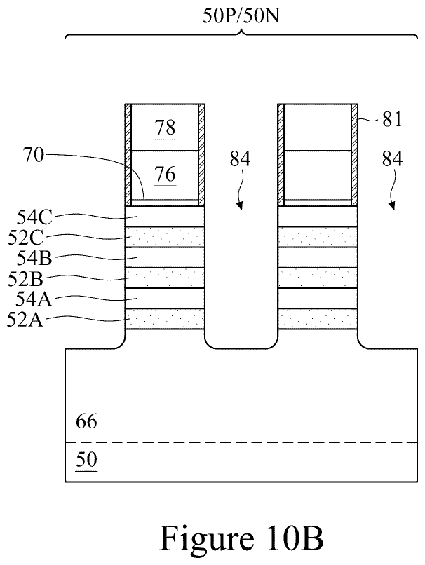

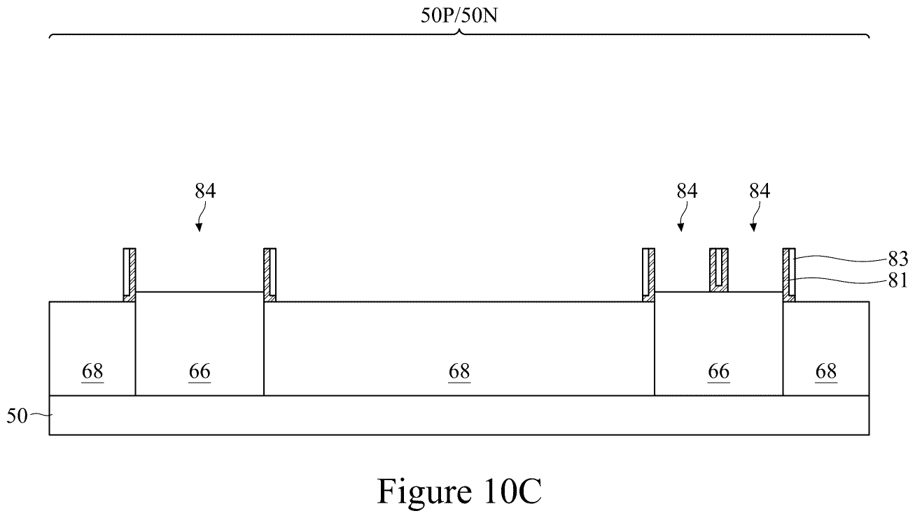

In FIGS. 10A-C, first recesses 84 are formed in the fins 66, the nanostructures 55, the sub-nanostructures 55′/55″, and the substrate 50, in accordance with some embodiments. Epitaxial source/drain regions will be subsequently formed in the first recesses 84. The first recesses 84 may extend through the first nanostructures 52 and the second nanostructures 54, and into the substrate 50. As illustrated in FIG. 10C, the fins 66 may be etched such that bottom surfaces of the first recesses 84 are disposed above or below the top surfaces of the STI regions 68. In other embodiments, top surfaces of the STI regions 68 may be level with bottom surfaces of the first recesses 84. The first recesses 84 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 84. A single etch process or multiple etch processes may be used to etch each layer of the nanostructures 55 and/or the fins 66. Timed etch processes may be used to stop the etching of the first recesses 84 after the first recesses 84 reach a desired depth.

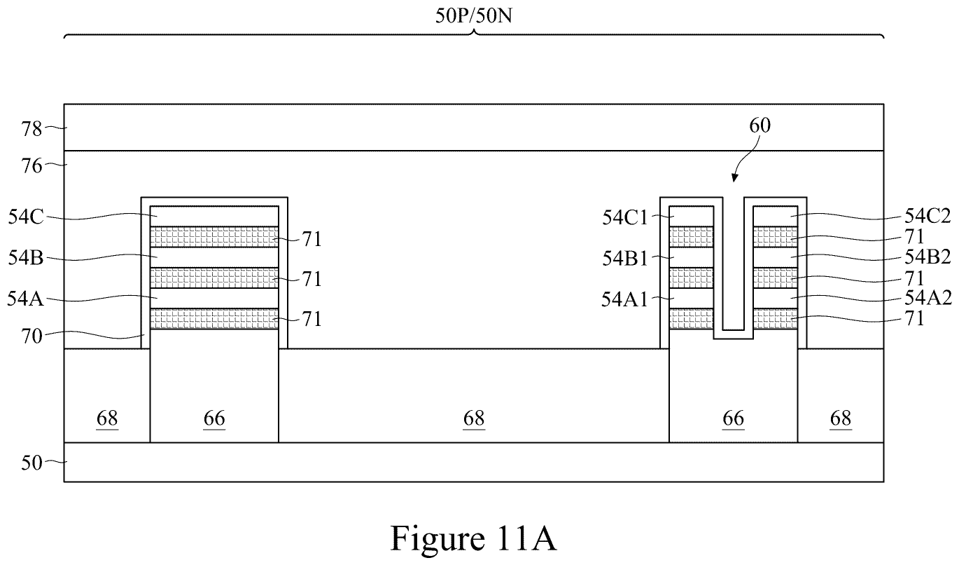

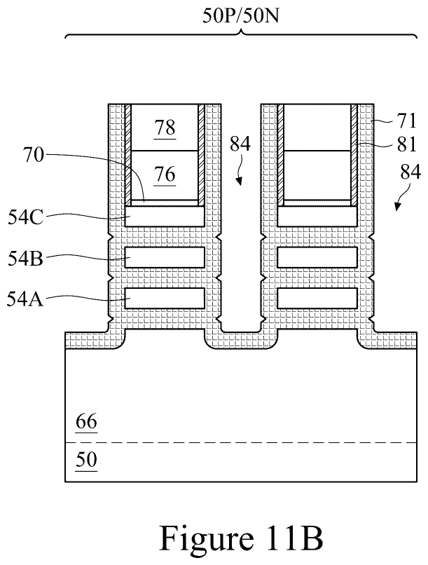

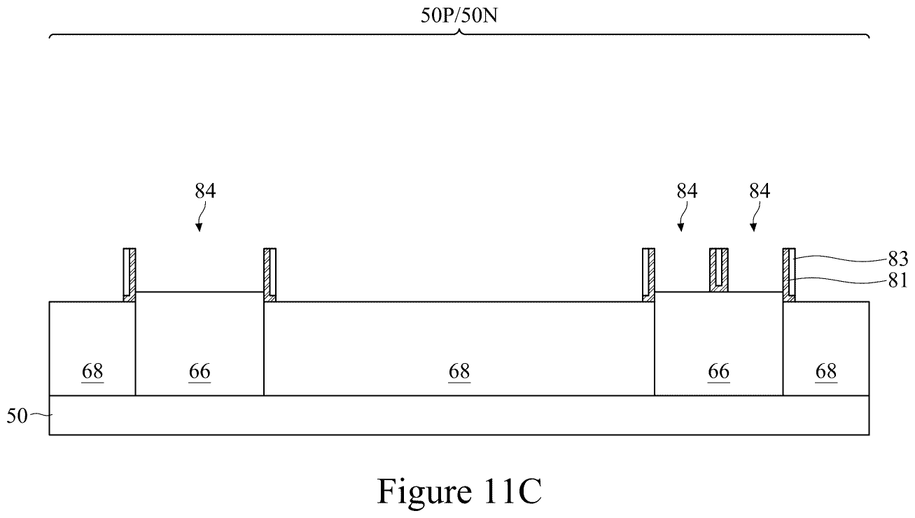

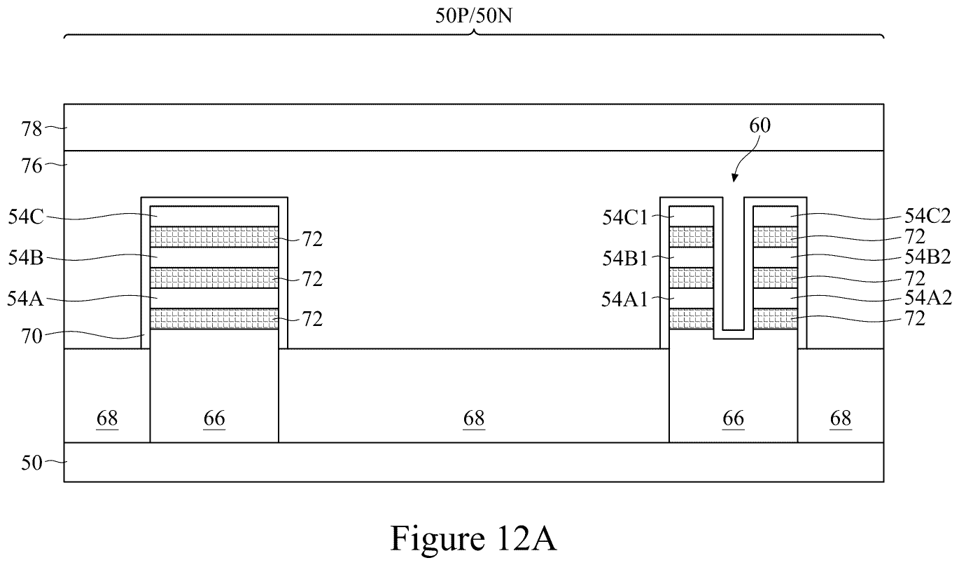

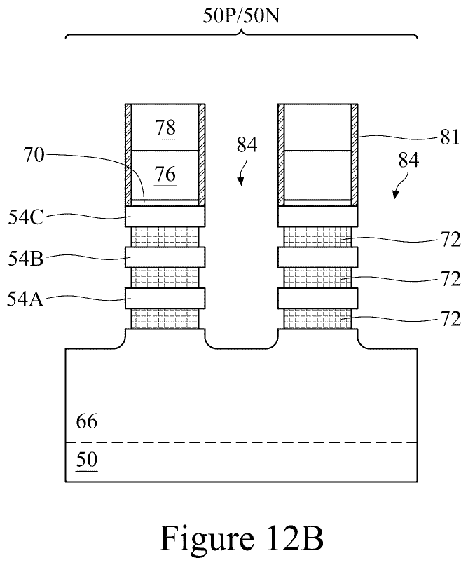

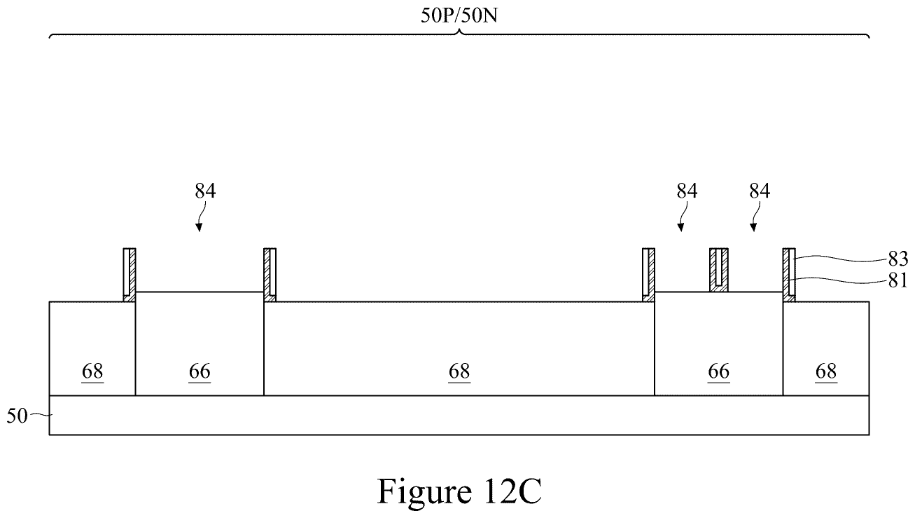

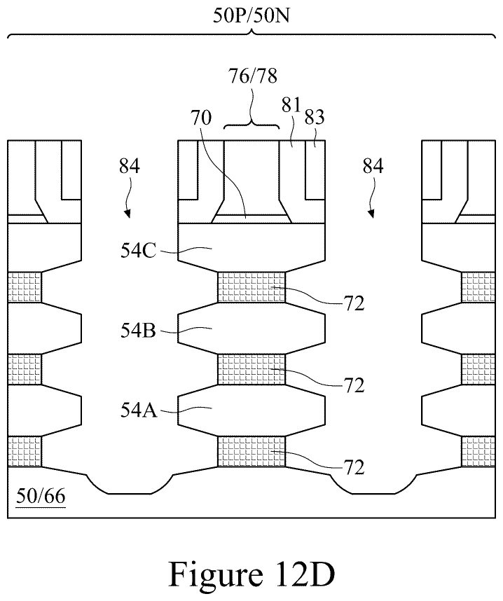

In FIGS. 11A-12D, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 84 as illustrated by FIGS. 11A-C. The etch process may be selective to the material of the first nanostructures 52 and remove the first nanostructures 52 without significantly removing the second nanostructures 54 or the fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the first recesses 84 and spaces where the first nanostructures 52 were removed. The sacrificial material layer 71 may be deposited by a conformal deposition process, such as CVD, ALD, or the like. The sacrificial material layer 71 may comprise an insulating material such as silicon oxide (e.g., SiO₂), silicon oxynitride, aluminum oxide, or the like that can be selectively etched from the second nanostructures 54.

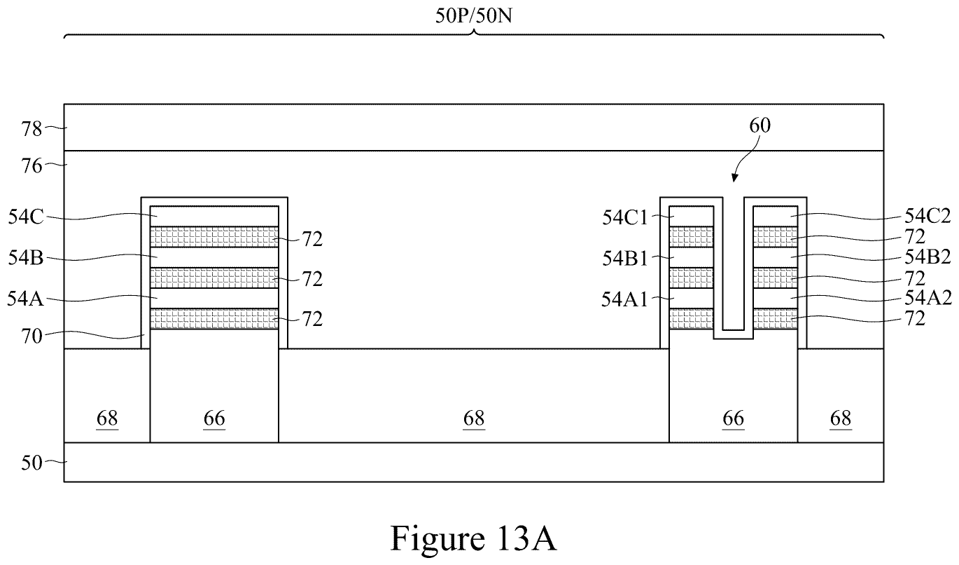

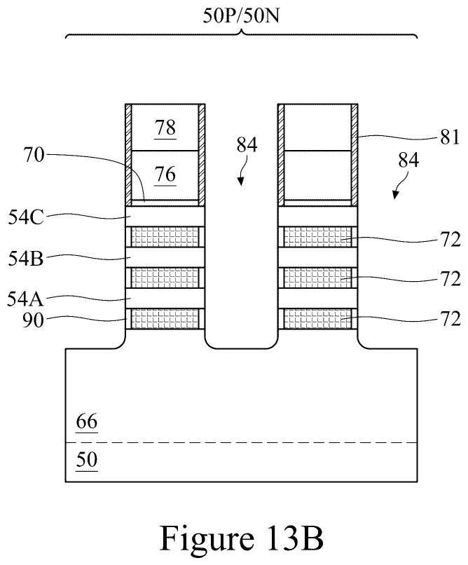

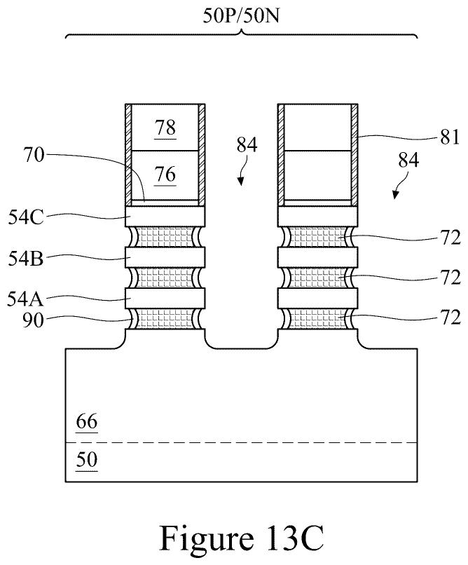

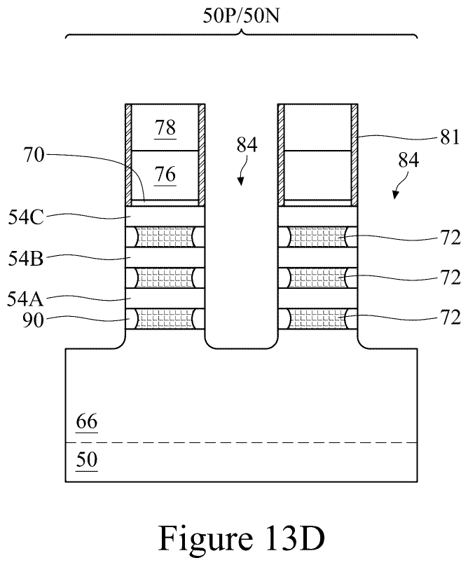

In FIGS. 12A-D, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 are recessed past sidewalls of the nanostructures 54. Although sidewalls of sacrificial material 72 are illustrated as being straight in FIGS. 12B and 12D, the sidewalls may be concave or convex (see e.g., FIG. 13C).

FIGS. 12B and 12D illustrate similar cross-sectional views in accordance with different embodiments. FIG. 12B illustrates a configuration of the structure that is similar to the previous figures showing nanostructures 54, gate structures 76/78, spacers 81, and sacrificial material 72 with planar surfaces and square corners. FIG. 12D on the other hand illustrates a configuration of the structure that shows the nanostructures 54, the gate structures 76/78, the spacers 81, and the sacrificial material 72 with non-planar surfaces and rounded corners. For example, FIG. 12D illustrate second nanostructures 54 that are thicker in the middle and thin towards the edges with rounded corners in the cross-sectional view. Further, FIG. 12D illustrates that the fins/substrate 66/50 exposed at the bottom of the recesses 84 has an indentation in the middle regions of the recesses 84. Although most of the figures in this disclosure illustrate the structures with planar surfaces and square corners, the scope of the disclosure is not limited thereto, as this disclosure also contemplates the structures having non-planar surfaces and rounded corner and profiles.

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material prior to the high-temperature processes (e.g., source/drain annealing), manufacturing defects can be reduced, and device performance can be improved (e.g., increased current drive, reduced capacitance, and improved short channel effect).

In FIGS. 13A and 13B, inner spacers 90 are formed in the first recesses 84 on the sidewalls of the sacrificial material 72. The inner spacers 90 act as isolation features between subsequently formed source/drain regions and a gate structure. As will be discussed in greater detail below, source/drain regions will be formed in the first recesses 84, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 12A and 12B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 13C). Moreover, although the outer sidewalls of the inner spacers 90 are illustrated as being straight in FIG. 13B, the outer sidewalls of the inner spacers 90 may be concave or convex. As an example, FIG. 13C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 13D illustrates an embodiment in which sidewalls of the sacrificial material 72 are concave, outer sidewalls of the inner spacers 90 are straight, and the inner spacers 90 are flush with sidewalls of the second nanostructures 54.

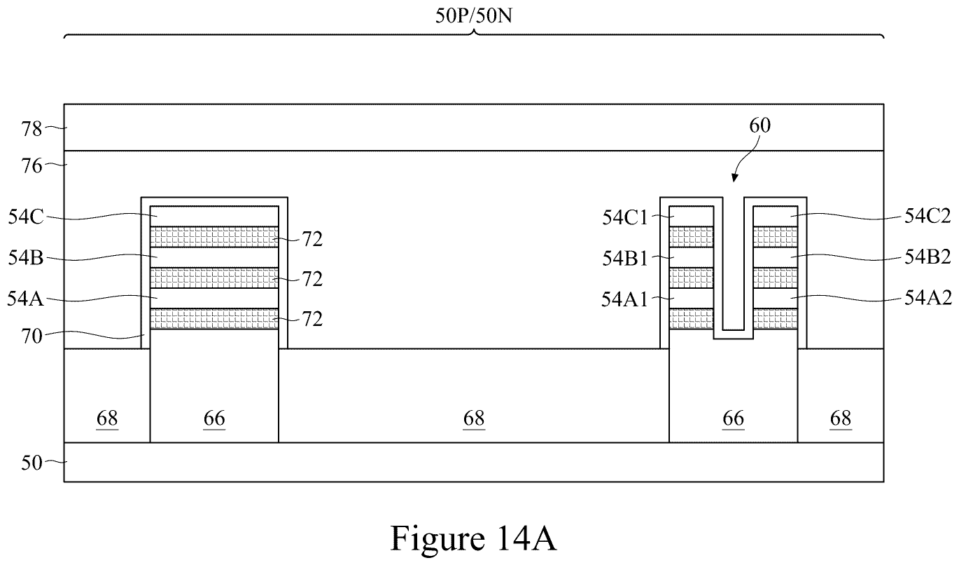

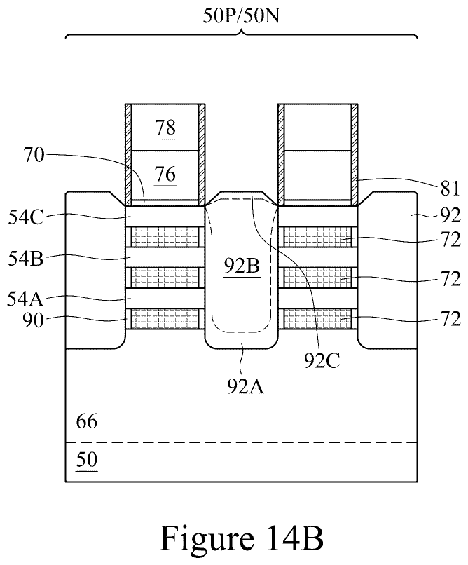

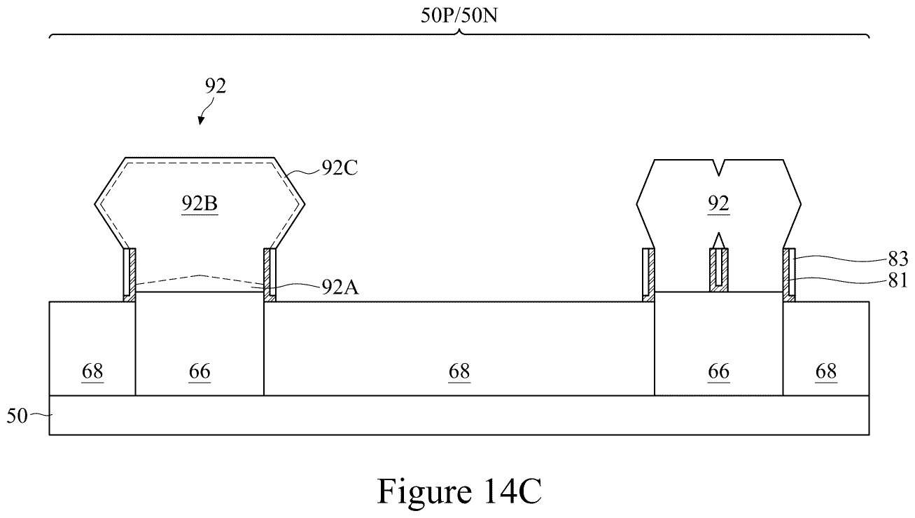

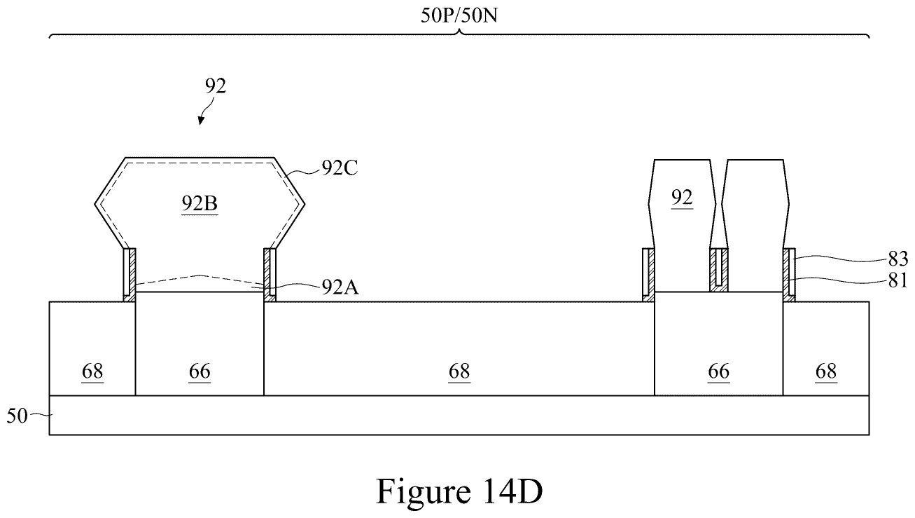

In FIGS. 14A-14D, epitaxial source/drain regions 92 are formed in the first recesses 84. In some embodiments, the source/drain regions 92 may exert stress on the second nanostructures 54 in the n-type region 50N and/or on the first nanostructures 52 in the p-type region 50P, thereby improving performance. As illustrated in FIG. 14B, the epitaxial source/drain regions 92 are formed in the first recesses 84 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 84 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as Si, SiP, SiAs, SiP+SiAs/SiSb, SiSb, SiP+SiAs+SiSb, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 84 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as SiGe, Ge, GeSn, SiB, SiGe:B, SiGe:Ga, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 14C. In other embodiments, adjacent epitaxial source/drain regions 92 remain separated after the epitaxy process is completed as illustrated by FIG. 14D. In the embodiments illustrated in FIGS. 14C and 14D, the fin spacers 83 may be formed on top surfaces of the STI regions 68, thereby blocking the epitaxial growth. In some other embodiments, the fin spacers 83 may cover portions of the sidewalls of the nanostructures 55 or the sub-nanostructures 55′/55″ further blocking the epitaxial growth. In some other embodiments, the spacer etch used to form the fin spacers 83 may be adjusted to remove the spacer material to allow the epitaxially grown region to extend to the surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

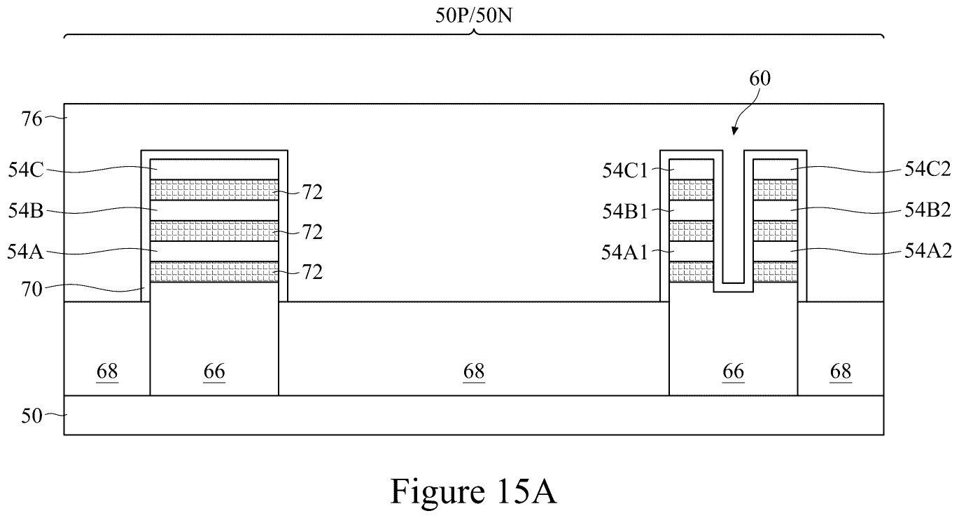

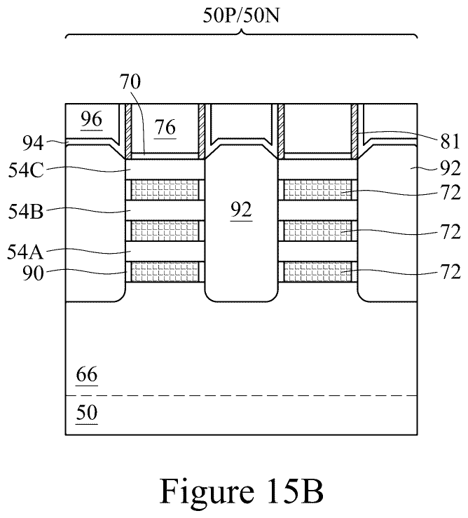

In FIGS. 15A and 15B, a first interlayer dielectric (ILD) 96 is deposited over the structure illustrated in FIGS. 14A and 14B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81 and 83. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

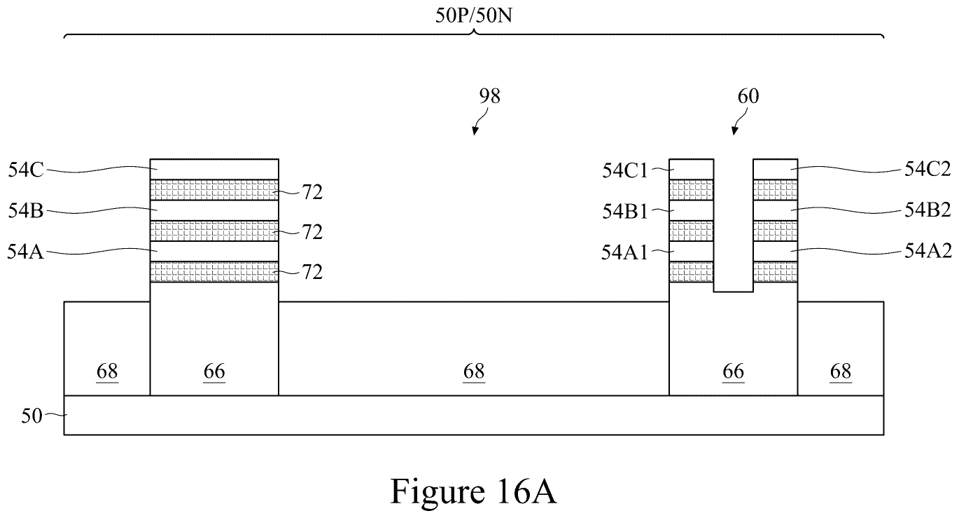

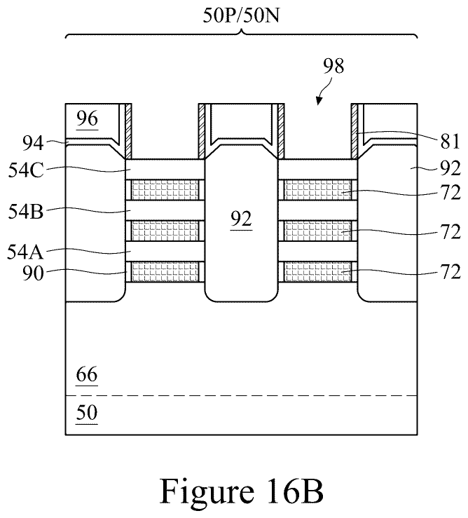

In FIGS. 16A and 16B, the dummy gates 76, and the masks 78 if present, are removed in one or more etching steps, so that second recesses 98 are formed and the portion of nanostructure cut 60 previously under the dummy gates 76 is exposed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55 and sub-nanostructures 55′/55″, which act as channel regions in subsequently completed nano-FETs. Portions of the nanostructures 55 and sub-nanostructures 55′/55″ which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

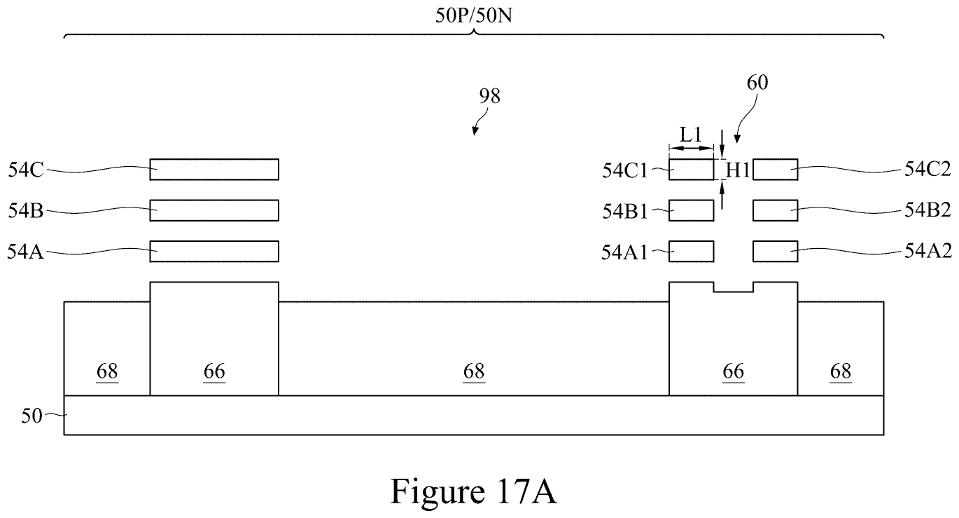

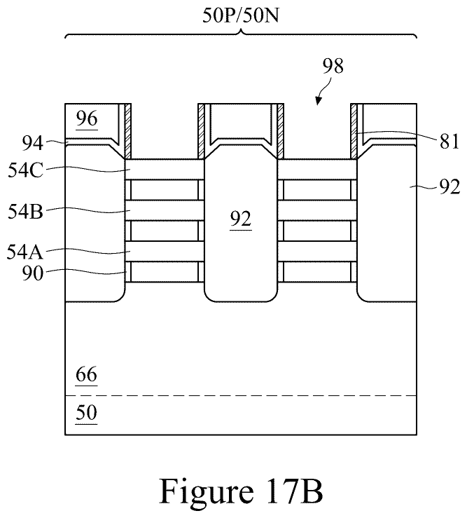

In FIGS. 17A and 17B, the sacrificial material 72 is removed, which extends the second recesses 98 to between the second nanostructures 54. In the sub-nanostructure 55″ with the longitudinal nanostructure cut 60, the second recesses are extended to the nanostructure cut 60 forming two separate vertical stacks of second nanostructures 54A1-C1 and 54A2-C2. As illustrated in FIG. 17A, each of the second nanostructures 54A1-C1 and 54A2-C2 may have a height H1 and a length L1. The height H1 is measured in a direction perpendicular to a major surface of the substrate 50. The length L1 is measured in a direction parallel to a major surface of the substrate 50. In some embodiments, the ratio of L1 to H1 is greater than 1. If the ratio of the L1 to H1 is less than 1, the structure may have more defects.

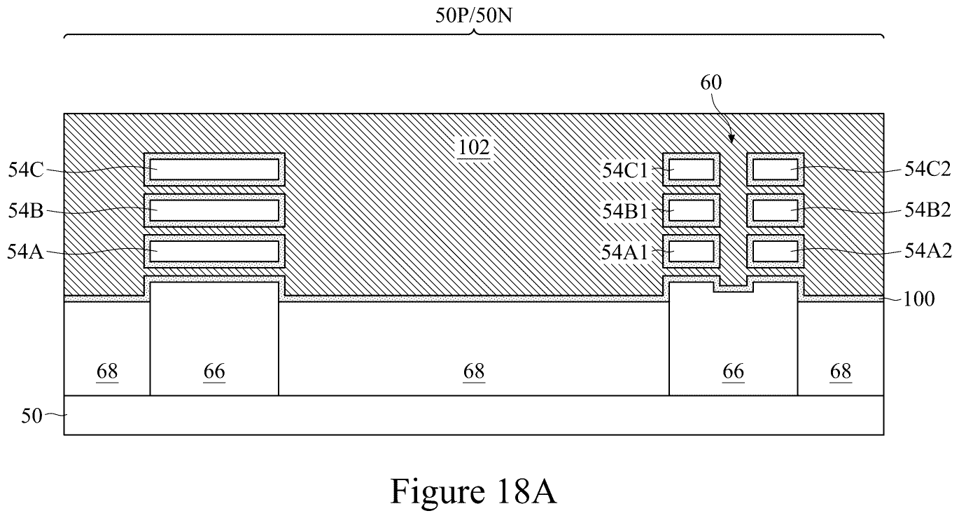

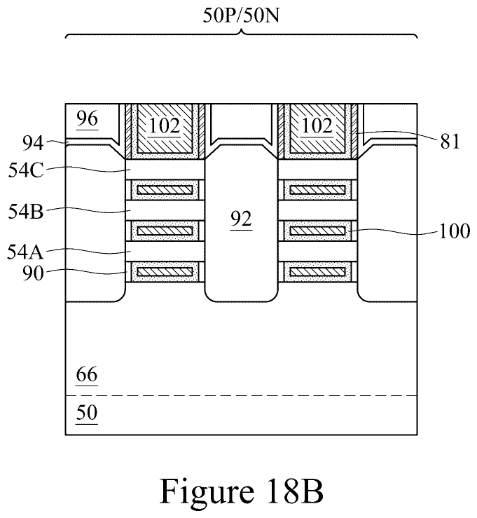

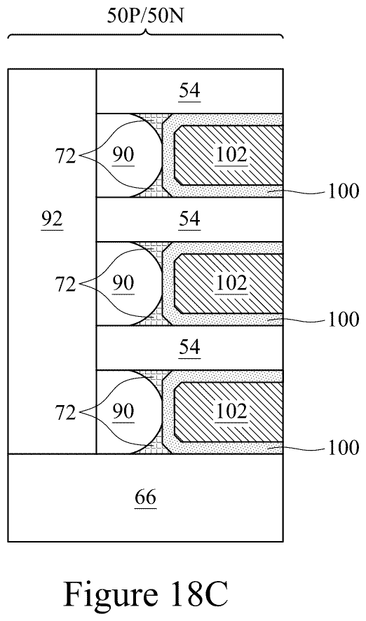

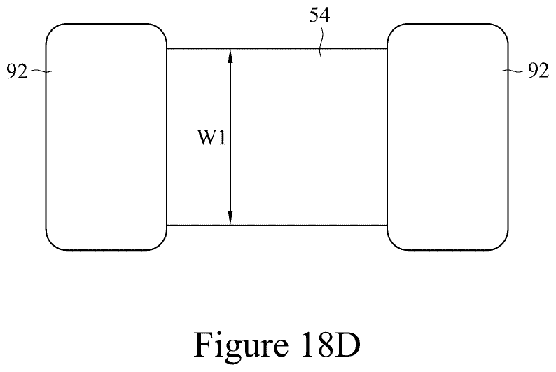

The removal of the sacrificial material 72 may involve an isotropic etching process, such as a wet etching using dilute hydrofluoric acid (HF) or a chemical oxide removal (COR) dry etch. These etchants are selective to the materials of the sacrificial material 72, ensuring that the second nanostructures 54 remain relatively unetched in comparison to the sacrificial material 72. The sacrificial material 72 may be completely removed, or a residue of the sacrificial material 72 may remain on sidewalls of the inner spacers in the second recesses 98 (see e.g., FIG. 18C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not shown) at a top surface to protect the underlying STI regions 68 from etching while patterning and removing the sacrificial material 72. In such embodiments, the hard mask may comprise, for example, a nitride.

In FIGS. 18A-18B, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the spacers 81 and 83, and the STI regions 68. As illustrated in FIG. 18A, the gate dielectric layers 100 are formed to surround each of the second nanostructures 54A1-C1 and 54A2-C2.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. As illustrated in FIG. 18A, the gate electrodes 102 are formed to surround each of the second nanostructures 54A1-C1 and 54A2-C2. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 18A-18C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 18C illustrates a detailed view of various elements of FIG. 18B, including the epitaxial source/drain regions 92, the gate dielectric layers 100, the gate electrodes 102, the second nanostructures 54, and the inner spacers 90. In some embodiments, illustrated by FIG. 18C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

FIG. 18D illustrates a plan view of a second nanostructure 54 and source/drain regions 92. The other structures are omitted from this view. In some embodiments, the second nanostructure 54 (may also be a sub-nanostructure 54) has a width W1. The width W1 may be consistent and uniform from one source/drain region 92 to another source/drain region 92 without significant reductions in portions of the second nanostructure 54. Said another way, the sidewall of the second nanostructure 54 between the source/drain regions 92 is a flat sidewall.

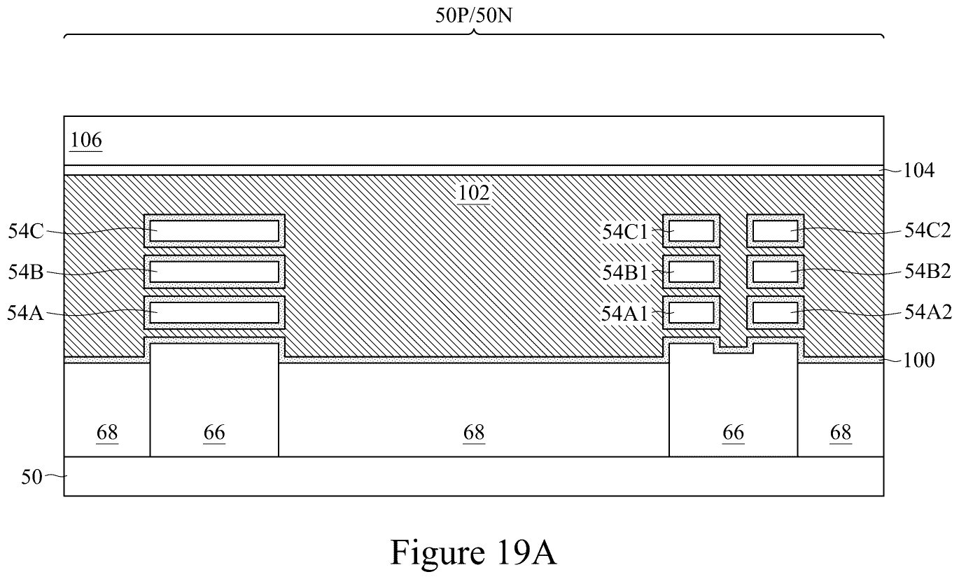

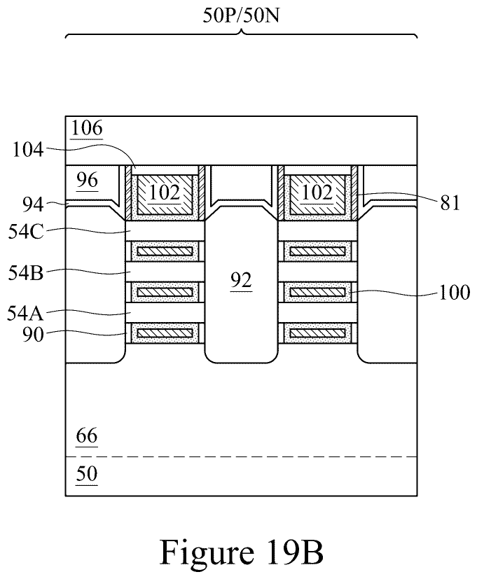

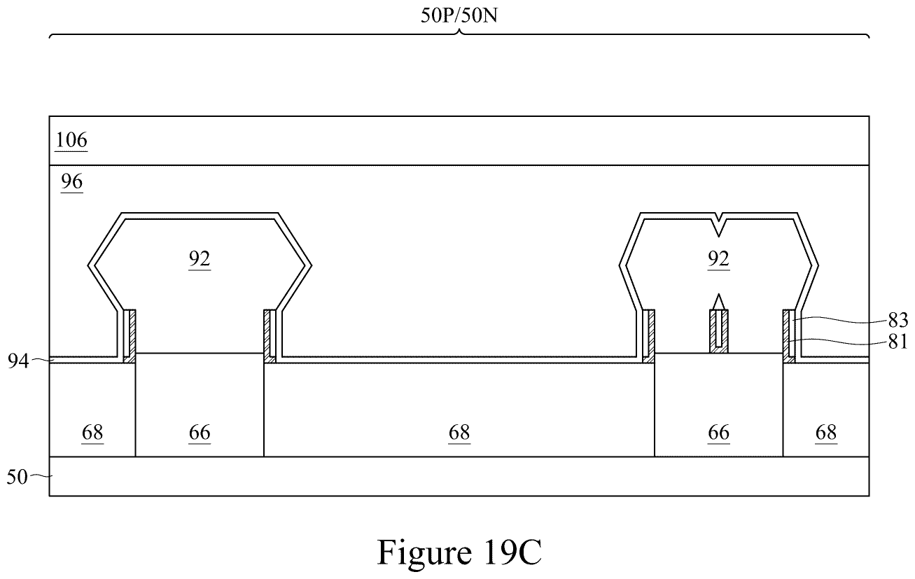

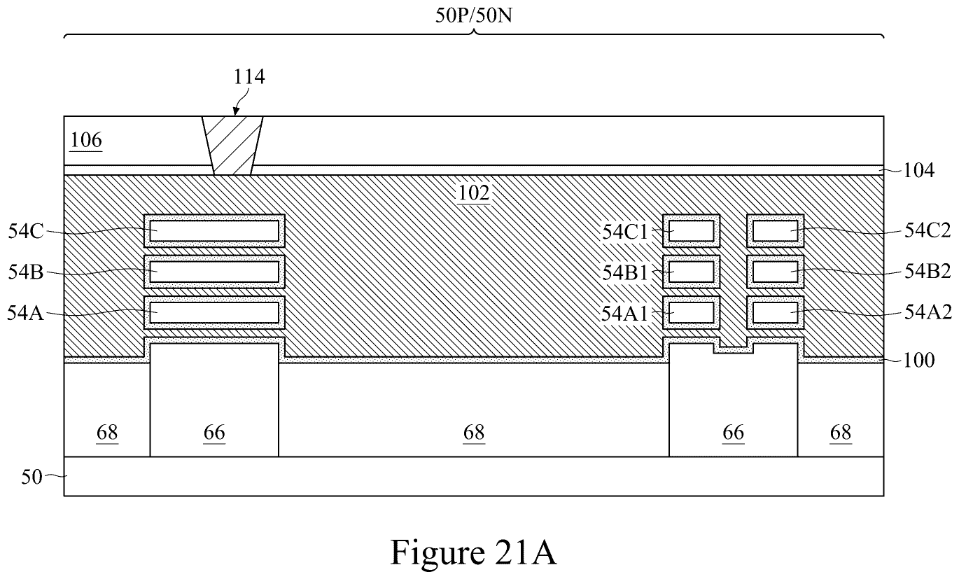

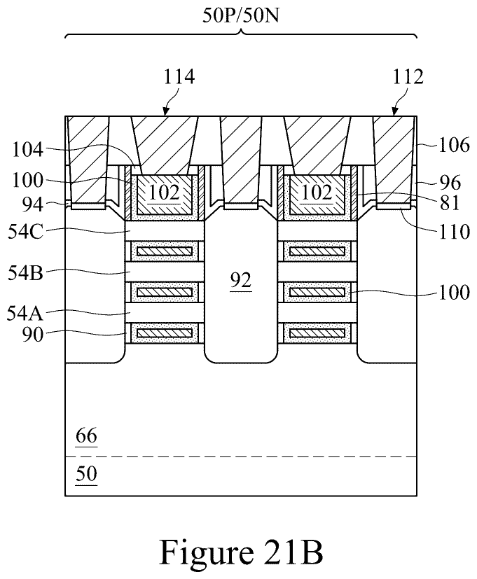

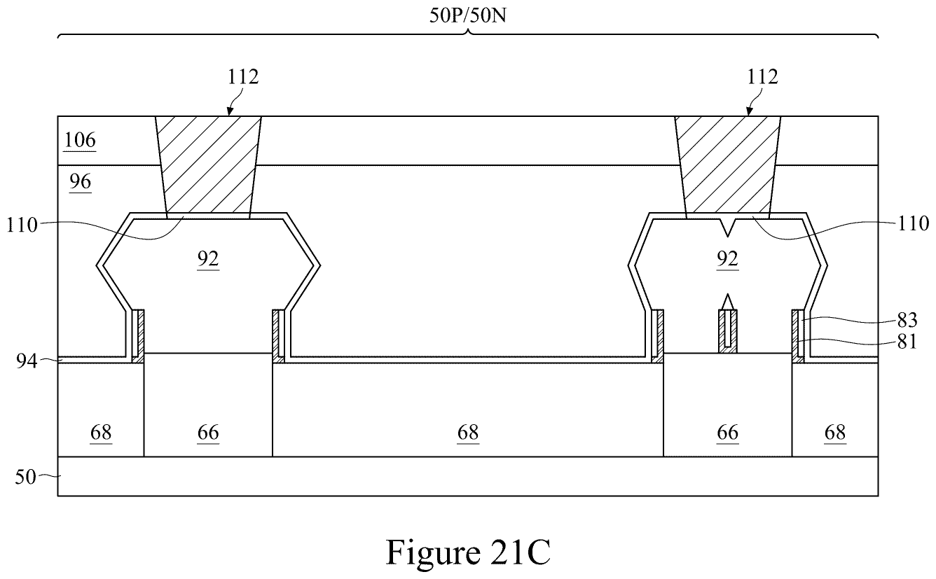

In FIGS. 19A-19C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 21A-21C) penetrate through the gate mask 104 to contact the top surface of the recessed gate electrodes 102.

As further illustrated by FIGS. 19A-19C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

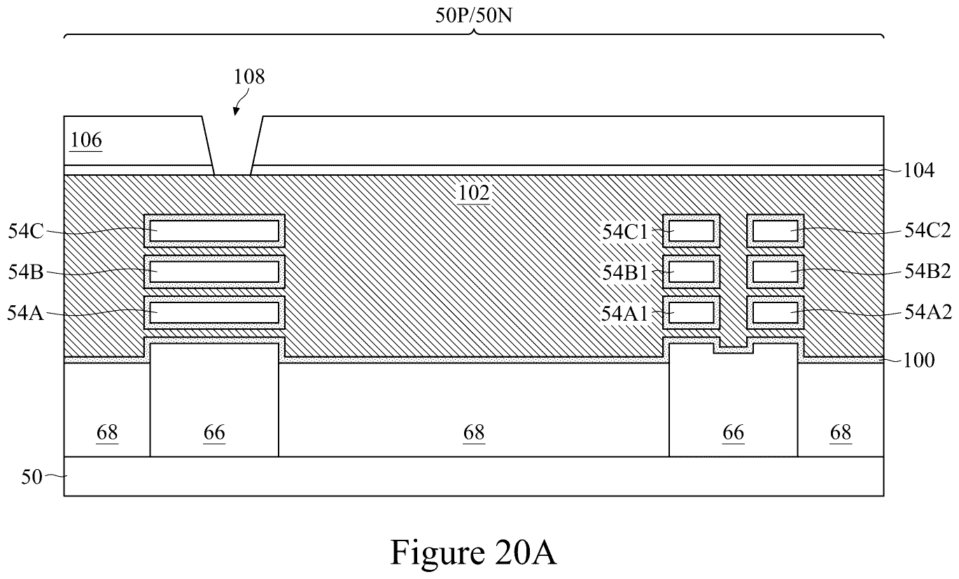

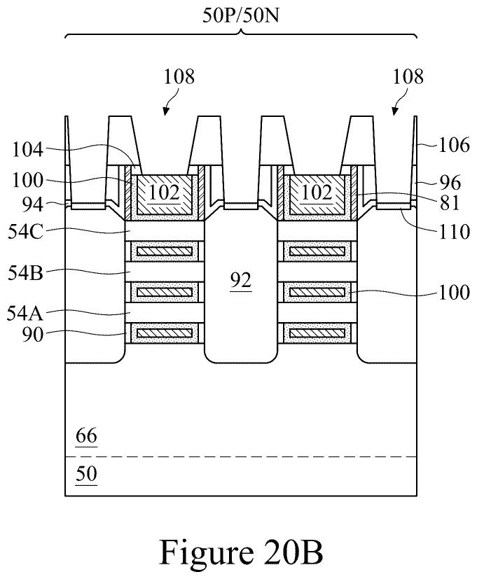

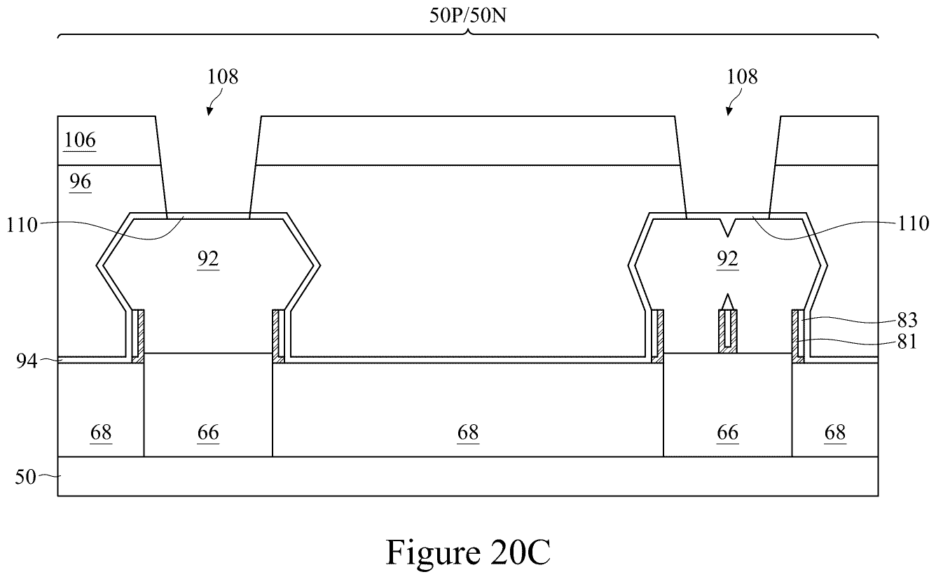

In FIGS. 20A-20C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 20B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 21A-21C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts 114, and the contacts 112 are electrically coupled to the silicide regions 110 and may be referred to as source/drain contacts 112. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

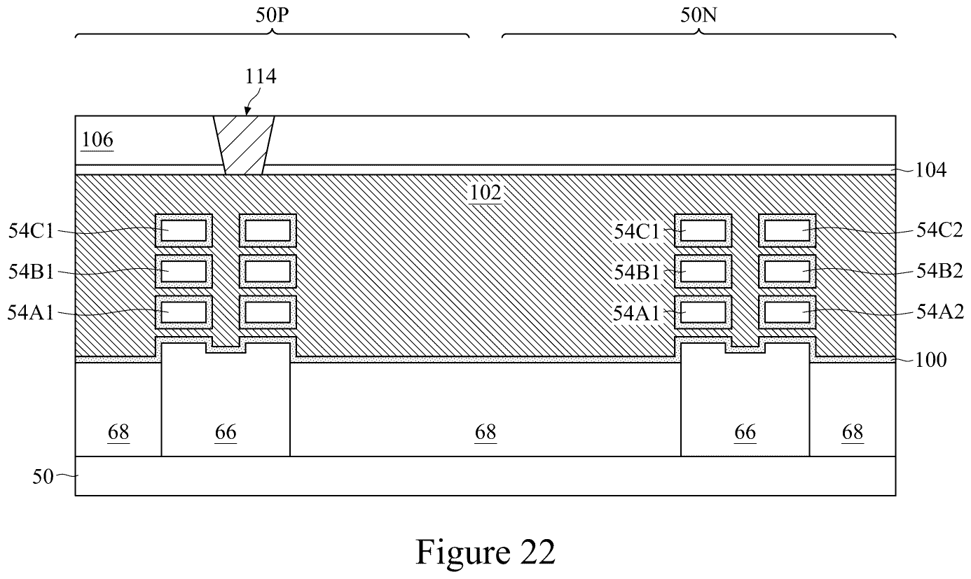

FIG. 22 illustrates a cross-sectional view of an intermediary step of manufacturing a nano-FET transistor, in accordance with some embodiments. FIG. 20 illustrates reference cross-section A-A′ illustrated in FIG. 1. In FIG. 22, like reference numerals indicate like elements formed by like processes as described above in FIGS. 2 through 21C unless otherwise indicated. FIG. 22 illustrates a similar step in processing as FIGS. 21A-C and the description is not repeated herein.

In FIG. 22, devices in both the n-type region 50N and the p-type region 50P have sub-nanostructures 55″ with longitudinal nanostructure cuts 60. In this embodiment, the effective channel width of these both the n-type and p-type devices can be increased. For example, in an SRAM configuration, the p-type pull-up transistors and the n-type pull-down and pass-gate transistors can all have increased effective channel width without increasing the overall area required for the devices using the disclosed embodiments.

FIG. 23 illustrates a cross-sectional view of an intermediary step of manufacturing a nano-FET transistor, in accordance with some embodiments. FIG. 23 illustrates a detailed view on the reference cross-section A-A′ illustrated in FIG. 1. In FIG. 23, like reference numerals indicate like elements formed by like processes as described above in FIGS. 2 through 21C unless otherwise indicated. FIG. 23 illustrates a similar step in processing as FIGS. 21A-C and focuses on the gate structure and nanostructures and the description is not repeated herein.

In this embodiment, a residue of the sacrificial material 72 may remain on surfaces of the lower second nanostructures (e.g., 54A1, 54A2, 54B1, and/or 54B2), such as between the second nanostructures 54 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device and the device can operate normally.

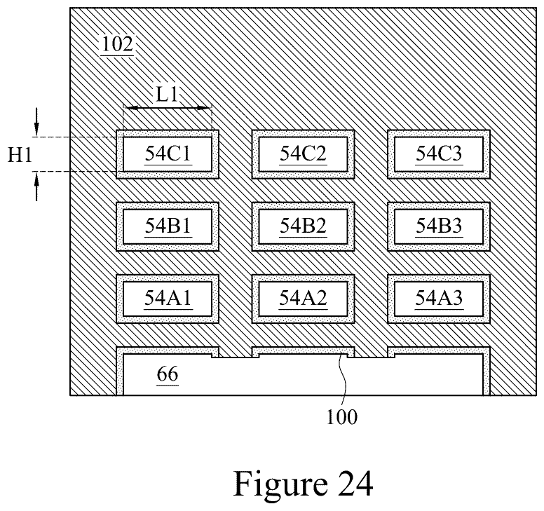

FIG. 24 illustrates a cross-sectional view of an intermediary step of manufacturing a nano-FET transistor, in accordance with some embodiments. FIG. 24 illustrates reference cross-section A-A′ illustrated in FIG. 1. In FIG. 24, like reference numerals indicate like elements formed by like processes as described above in FIGS. 2 through 21C unless otherwise indicated. FIG. 24 illustrates a similar step in processing as FIGS. 21A-C and focuses on the gate structure and nanostructures and the description is not repeated herein.

In this embodiment, there have been two second nanostructure cuts 60 made on a single stack of nanostructures 55 to form three vertical stacks of second nanostructures 54A1-C1, 54A2-C2, and 54A3-C3. Similar to the previous embodiments, each of the second nanostructures 54A1-C1, 54A2-C2, and 54A3-C3 have a height H1 and a length L1. In some embodiments, the ratio of L1 to H1 is greater than 1. If the ratio of the L1 to H1 is less than 1, the structure may have more defects.

This embodiment with the three vertical stacks (e.g., nine separate nanostructures 54A1-C3 from the same fin stack) can result in further improved cell current and optimization of minimum operating voltage for an SRAM configuration as compared to the embodiment with two vertical stacks.

Embodiments may achieve advantages. The disclosed embodiments incorporate DOI engineering for nanosheet Static Random Access Memory (SRAM) cells. By increasing the effective width of pass-gate (PG) and pull-down (PD) transistors, the structure optimizes SRAM cell performance and mitigates current crowding issues that become more pronounced at smaller nodes. The DOI scheme minimizes sheet-width loss during the sheet-release stage of fabrication, resulting in substantial improvements in DC performance and reduced variability. In some embodiments, the pull-up (PU) transistors also have increased effective width.

The fabrication process utilizes nanostructure cut techniques, allowing for flexible implementation through either separate or single cut active area masks for NMOS and PMOS devices. This approach enables the creation of optimized transistor structures for both n-type and p-type devices within the same manufacturing process, facilitating the production of complementary metal-oxide-semiconductor (CMOS) circuits with enhanced performance characteristics.

There are several advantages of the disclosed semiconductor device and fabrication method. The increased effective width of PG and PD transistors not only optimizes SRAM cell performance but also reduces current crowding, resulting in improved read and write margins and enhanced overall cell stability. These improvements help maintain reliable SRAM operation as supply voltages are scaled down in advanced nodes.

The DOI scheme's ability to minimize sheet-width loss translates directly into gains in DC performance. This is useful for SRAM applications, where fast switching speeds and low power consumption are advantageous. The optimized structure achieves an 8-15% improvement in cell current, which directly correlates to faster SRAM operation speeds and improved overall performance metrics.

Furthermore, the enhanced PG/PD performance allows for optimization of the SRAM Cell V_{ccmin} (minimum operating voltage), enabling reliable operation at lower supply voltages. Specifically, the optimized structure results in a 17-33% improvement for the SRAM cell V_{ccmin}. This capability helps to reduce power consumption in modern semiconductor devices, particularly in mobile and battery-powered applications where energy efficiency is more beneficial.

The combination of these advancements-improved electrostatic control, enhanced DC performance, increased cell current, and lower operating voltages-makes this nano-FET structure and method a solution for the continued scaling of SRAM technology in advanced semiconductor nodes. By addressing challenges of transistor scaling while simultaneously improving performance metrics, disclosed embodiments enable high-performance, low-power semiconductor devices.

In an embodiment, a method may include forming a multi-layer stack over a substrate, the multi-layer stack having alternating layers of first semiconductor layers and second semiconductor layers. The method may also include patterning the multi-layer stack to form a first fin. The method may furthermore include patterning the first fin to form two sub-fins. The method may in addition include forming recesses in the two sub-fins. The method may moreover include selectively removing the first semiconductor layers. The method may also include forming a sacrificial material between the second semiconductor layers. The method may furthermore include growing epitaxial source/drain regions in the recesses. The method may in addition include replacing the sacrificial material with an active gate structure.

The described embodiments may also include one or more of the following features. The method where the sacrificial material may include silicon oxide, silicon oxynitride, aluminum oxide, or combinations thereof. The method where the first semiconductor layers may include silicon germanium and the second semiconductor layers may include silicon. The method may include forming inner spacers between the second semiconductor layers prior to growing the epitaxial source/drain regions. The method where patterning the first fin to form two sub-fins may include patterning the first fin along a longitudinal axis of the first fin. The method where patterning the first fin to form two sub-fins may include patterning the first fin perpendicular to a longitudinal axis of the first fin. The method further may include patterning the multi-layer stack to form a second fin, and forming a dummy gate structure over the second fin and the two sub-fins. The method where the dummy gate structure extends along sidewalls and top surfaces of the two sub-fins, the dummy gate structure extending between the two sub-fins. The method where the two sub-fins and the active gate structure are part of an n-type transistor, and where the second fin and the active gate structure are part of a p-type transistor.

In an embodiment, a method may include forming a first fin and a second fin of a multi-layer stack over a substrate, the multi-layer stack including alternating layers of first semiconductor layers and second semiconductor layers. The method may also include patterning the first fin to form two sub-fins. The method may furthermore include forming a first gate structure over the two sub-fins and the second fin. The method may in addition include etching first recesses into the two sub-fins and the second fin. The method may moreover include removing the first semiconductor layers from the two sub-fins and the second fin. The method may also include forming a dielectric material between the second semiconductor layers and in the first recesses. The method may furthermore include recessing sidewalls of the dielectric material in the first recesses to form second recesses between adjacent second semiconductor layers. The method may in addition include forming inner spacers on the recessed sidewalls of the dielectric material. The method may moreover include forming source/drain regions in the first recesses adjacent to the inner spacers and the second semiconductor layers. The method may also include and replacing the first gate structure and the dielectric material with a metal gate structure.

The described embodiments may also include one or more of the following features. The method where after patterning the first fin to form two sub-fins, the two sub-fins are narrower than the second fin and have a same length as the second fin. The method where after patterning the first fin to form two sub-fins, the two sub-fins are shorter than the second fin and have a same width as the second fin. The method where the first semiconductor layers may include silicon germanium and the second semiconductor layers may include silicon. The method may include forming a shallow trench isolation region adjacent to the first fin and the second fin prior to forming the first gate structure. The method where the metal gate structure may include a high-k dielectric layer surrounding the second semiconductor layers and a metal gate electrode surrounding the high-k dielectric layer.

In an embodiment, a semiconductor device may include a first fin and a second fin over a substrate. The semiconductor device may also include a first stack of semiconductor nanostructures disposed on the first fin, the first stack having at least two sub-stacks separated by a gap, where each sub-stack includes a plurality of vertically arranged channel layers. The semiconductor device may furthermore include a second stack of semiconductor nanostructures disposed on the second fin, where the second stack includes a plurality of vertically arranged channel layers. The semiconductor device may in addition include a gate structure wrapping around each of the channel layers in the at least two sub-stacks and the second stack, the gate structure having a gate dielectric layer and a gate electrode. The semiconductor device may moreover include epitaxial source/drain regions disposed on opposite sides of the gate structure and in contact with end portions of the channel layers. The semiconductor device may also include inner spacers disposed between the channel layers and adjacent to the epitaxial source/drain regions, where the channel layers in the at least two sub-stacks have a different width than the channel layers in the second stack.

The described embodiments may also include one or more of the following features. The semiconductor device where the channel layers in the at least two sub-stacks are narrower than the channel layers in the second stack. The semiconductor device may include a shallow trench isolation region adjacent to the first fin and the second fin. The semiconductor device where the at least two sub-stacks may include two sub-stacks separated by a gap along a longitudinal axis of the first fin. The semiconductor device where the first stack of semiconductor nanostructures and the gate structure form an n-type transistor, and the second stack of semiconductor nanostructures and the gate structure form a p-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a multi-layer stack over a substrate, the multi-layer stack comprising alternating layers of first semiconductor layers and second semiconductor layers;
patterning the multi-layer stack to form a first fin;
patterning the first fin to form two sub-fins;
forming recesses in the two sub-fins;
selectively removing the first semiconductor layers;
forming a sacrificial material between the second semiconductor layers;
growing epitaxial source/drain regions in the recesses; and
replacing the sacrificial material with an active gate structure.

2. The method of claim 1, wherein the sacrificial material comprises silicon oxide, silicon oxynitride, aluminum oxide, or combinations thereof.

3. The method of claim 1, wherein the first semiconductor layers comprise silicon germanium and the second semiconductor layers comprise silicon.

4. The method of claim 1, further comprising forming inner spacers between the second semiconductor layers prior to growing the epitaxial source/drain regions.

5. The method of claim 1, wherein patterning the first fin to form two sub-fins comprises patterning the first fin along a longitudinal axis of the first fin.

6. The method of claim 1, wherein patterning the first fin to form two sub-fins comprises patterning the first fin perpendicular to a longitudinal axis of the first fin.

7. The method of claim 1 further comprising:
patterning the multi-layer stack to form a second fin; and
forming a dummy gate structure over the second fin and the two sub-fins.

8. The method of claim 7, wherein the dummy gate structure extends along sidewalls and top surfaces of the two sub-fins, the dummy gate structure extending between the two sub-fins.

9. The method claim 7, wherein the two sub-fins and the active gate structure are part of an n-type transistor, and wherein the second fin and the active gate structure are part of a p-type transistor.

10. A method, comprising:
forming a first fin and a second fin of a multi-layer stack over a substrate, the multi-layer stack including alternating layers of first semiconductor layers and second semiconductor layers;
patterning the first fin to form two sub-fins;
forming a first gate structure over the two sub-fins and the second fin;
etching first recesses into the two sub-fins and the second fin;
removing the first semiconductor layers from the two sub-fins and the second fin;
forming a dielectric material between the second semiconductor layers and in the first recesses;
recessing sidewalls of the dielectric material in the first recesses to form second recesses between adjacent second semiconductor layers;
forming inner spacers on the recessed sidewalls of the dielectric material;
forming source/drain regions in the first recesses adjacent to the inner spacers and the second semiconductor layers; and
replacing the first gate structure and the dielectric material with a metal gate structure.

11. The method of claim 10, wherein after patterning the first fin to form two sub-fins, the two sub-fins are narrower than the second fin and have a same length as the second fin.

12. The method of claim 10, wherein after patterning the first fin to form two sub-fins, the two sub-fins are shorter than the second fin and have a same width as the second fin.

13. The method of claim 10, wherein the first semiconductor layers comprise silicon germanium and the second semiconductor layers comprise silicon.

14. The method of claim 10, further comprising forming a shallow trench isolation region adjacent to the first fin and the second fin prior to forming the first gate structure.

15. The method of claim 10, wherein the metal gate structure comprises a high-k dielectric layer surrounding the second semiconductor layers and a metal gate electrode surrounding the high-k dielectric layer.

16. A semiconductor device, comprising:
a first fin and a second fin over a substrate;
a first stack of semiconductor nanostructures disposed on the first fin, the first stack comprising at least two sub-stacks separated by a gap, wherein each sub-stack includes a plurality of vertically arranged channel layers;
a second stack of semiconductor nanostructures disposed on the second fin, wherein the second stack includes a plurality of vertically arranged channel layers;
a gate structure wrapping around each of the channel layers in the at least two sub-stacks and the second stack, the gate structure comprising a gate dielectric layer and a gate electrode;
epitaxial source/drain regions disposed on opposite sides of the gate structure and in contact with end portions of the channel layers; and
inner spacers disposed between the channel layers and adjacent to the epitaxial source/drain regions,
wherein the channel layers in the at least two sub-stacks have a different width than the channel layers in the second stack.

17. The semiconductor device of claim 16, wherein the channel layers in the at least two sub-stacks are narrower than the channel layers in the second stack.

18. The semiconductor device of claim 16, further comprising a shallow trench isolation region adjacent to the first fin and the second fin.

19. The semiconductor device of claim 16, wherein the at least two sub-stacks comprise two sub-stacks separated by a gap along a longitudinal axis of the first fin.

20. The semiconductor device of claim 16, wherein the first stack of semiconductor nanostructures and the gate structure form an n-type transistor, and the second stack of semiconductor nanostructures and the gate structure form a p-type transistor.
